(19) United States
(12) Patent Application Publication
(10) Pub. No.: US 2025/0259787 A1
(43) Pub. Date: Aug. 14, 2025

(54) CERAMIC ELECTRONIC DEVICE, PACKAGE, CIRCUIT BOARD AND MANUFACTURING METHOD OF CERAMIC ELECTRONIC DEVICE

(71) Applicant: TAIYO YUDEN CO., LTD., Tokyo (JP)

(72) Inventors: Shohei KITAMURA, Tokyo (JP); Ayumi SHIROTA, Tokyo (JP); Ayumi MATSUOKA, Tokyo (JP); Hikari ASAKO, Tokyo (JP)

(73) Assignee: TAIYO YUDEN CO., LTD., Tokyo (JP)

(21) Appl. No.: 19/076,697

(22) Filed: Mar. 11, 2025

Related U.S. Application Data
(63) Continuation of application No. PCT/JP2023/035788, filed on Sep. 29, 2023.

(30) Foreign Application Priority Data
Sep. 30, 2022 (JP) 2022-158517
Sep. 30, 2022 (JP) 2022-158955

(51) Int. Cl. H01G 4/008; H01G 2/06; H01G 4/30

(52) U.S. Cl. CPC H01G 4/0085; H01G 2/06; H01G 4/30

(57) ABSTRACT

A ceramic electronic device includes a multilayer chip in which a plurality of internal electrode layers are alternately exposed to opposing first and second end faces, and a pair of external electrodes that are formed respectively on the first end face and the second end face and have contact layers respectively contacting the first end face and the second end face and containing Cu as a main component. The plurality of internal electrode layers and the contact layers contain a low melting point metal having a melting point lower than that of Cu. One or more of the plurality of internal electrode layers from an outermost one have a connection portion connected to one of the pair of external electrodes, a width of the connection portion being narrower than other region of the one or more of the plurality of internal electrode layers.

### CROSS-REFERENCE TO RELATED APPLICATION

This application is a continuation application of PCT/JP2023/035788 filed on Sep. 29, 2023, which claims priority to Japanese Patent Application No. 2022-158955 filed on Sep. 30, 2022 and Japanese Patent Application No. 2022-158517 filed on Sep. 30, 2022, the contents of which are herein wholly incorporated by reference.

### FIELD

A certain aspect of the present invention relates to a ceramic electronic device, a package, a circuit board, and a manufacturing method of the ceramic electronic device.

### BACKGROUND

In recent years, electronic devices such as portable information terminals have become smaller, limiting the mounting area of ceramic electronic devices on a circuit board. On the other hand, the increasing sophistication of devices has created a demand for even larger capacity for multilayer ceramic capacitors.

### SUMMARY OF THE INVENTION

According to an aspect of the present invention, there is provided a ceramic electronic device including: a multilayer chip that has a substantially rectangular parallelepiped shape in which a plurality of dielectric layers and a plurality of internal electrode layers of which a main component is Ni are alternately stacked, and is formed so that the plurality of internal electrode layers are alternately exposed to opposing first and second end faces of the rectangular parallelepiped shape; and a pair of external electrodes that are formed respectively on the first end face and the second end face and have contact layers respectively contacting the first end face and the second end face and containing Cu as a main component, wherein the plurality of internal electrode layers and the contact layers contain a low melting point metal having a melting point lower than that of Cu, and wherein one or more of the plurality of internal electrode layers from an outermost one have a connection portion connected to one of the pair of external electrodes, a width of the connection portion being narrower than other region of the one or more of the plurality of internal electrode layers.

According to another aspect of the present invention, there is provided a package including: the above-mentioned ceramic electronic device, a carrier tape that has a sealing surface orthogonal to a first direction, and a recess recessed in the first direction from the sealing surface for housing the ceramic electronic component; and a top tape that is attached to the sealing surface and cover the recess, wherein the first direction and a second direction are orthogonal to a direction in which the first end face and the second end face are opposite to each other and are orthogonal to each other.

According to another aspect of the present invention, there is provided a circuit board including: a ceramic electronic device as mentioned above; and a mounting board that has a mounting surface orthogonal to a first direction, and a pair of connection electrodes each of which is connected to each of the pair of external electrodes of the ceramic electronic device via a solder, wherein the first direction and a second direction are orthogonal to a direction in which the first end face and the second end face are opposite to each other and are orthogonal to each other.

According to another aspect of the present invention, there is provided a manufacturing method of a ceramic electronic device including: firing a multilayer structure in which a plurality of stack units are stacked, each of the stack units having a structure in which an internal electrode pattern which is made of Ni as a main component and to which a low melting point metal having a lower melting point than Cu is added is formed on a dielectric green sheet; and forming a layer including the low melting metal as a main component on a first end face and a second end face of the multilayer structure before firing the multilayer structure of after firing the multilayer structure, wherein, in internal electrode patterns of one or more layers from an outermost layer among the plurality of internal electrode patterns, a width of a connection portion connected to the layer including the low melting point metal is narrower than a width of other region of the connection portion.

According to another aspect of the present invention, there is provided a manufacturing method of a ceramic electronic device including: firing a multilayer structure in which a plurality of stack units are stacked, each of the stack units having a structure in which an internal electrode pattern which is made of Ni as a main component and to which a low melting point metal having a lower melting point than Cu is added is formed on a dielectric green sheet; and forming a layer including the low melting metal as a main component on a first end face and a second end face of the multilayer structure before firing the multilayer structure of after firing the multilayer structure, wherein, in internal electrode patterns of one or more layers from an outermost layer among the plurality of internal electrode patterns, a width of a connection portion connected to the layer including the low melting point metal is narrower than a width of other region of the connection portion.

According to another aspect of the present invention, there is provided a package including: the ceramic electronic device as mentioned above, a carrier tape that has a sealing surface orthogonal to the first direction, and a recess recessed in the first direction from the sealing surface for housing the ceramic electronic component; and a top tape that is attached to the sealing surface and cover the recess.

According to another aspect of the present invention, there is provided a circuit board including: the ceramic electronic device as mentioned above; and a mounting board that has a mounting surface orthogonal to the first direction, and a pair of connection electrodes each of which is connected to each of the pair of external electrodes of the ceramic electronic device via a solder.

According to another aspect of the present invention, there is provided a manufacturing method of a ceramic electronic device of which a size in a first direction is 1.3 times or more of a size in a second direction orthogonal to the first direction, the method including: firing a multilayer structure in which a plurality of stack units are stacked in the second direction, each of the stack units having a structure in which an internal electrode pattern which is made of Ni as a main component and to which a low melting point metal having a lower melting point than Cu is added is formed on a dielectric green sheet; and forming a layer including Cu on a first end face and a second end face of the multilayer structure opposing in a third direction orthogonal to the first direction and the second direction before firing the multilayer structure of after firing the multilayer structure.

### BRIEF DESCRIPTION OF THE DRAWINGS

FIG. 1A and FIG. 1B illustrate a perspective view of a multilayer ceramic capacitor in which a cross section of a part of the multilayer ceramic capacitor is illustrated;

FIG. 2 illustrates a cross sectional view taken along a line A-A of FIG. 1A;

FIG. 3 illustrates a cross sectional view taken along a line B-B of FIG. 1A;

FIG. 4 is an enlarged cross-sectional view of a vicinity of an external electrode;

FIG. 5 illustrates a crack;

FIG. 6 illustrates a first section and a second section;

FIG. 7 illustrates a dimension “e”;

FIG. 8 illustrates a manufacturing method of a multilayer ceramic capacitor;

FIG. 9 is a side view of a circuit board including a multilayer ceramic capacitor;

FIG. 10 is a partial plan view of a package;

FIG. 11 is a cross-sectional view of a package;

FIG. 12A and FIG. 12B are partial cross-sectional perspective views of a multilayer ceramic capacitor according to a second embodiment;

FIG. 13A and FIG. 13B are partial cross-sectional perspective views of a multilayer ceramic capacitor according to a third embodiment;

FIG. 14 illustrates a stacking process;

FIG. 15A and FIG. 15B are partial cross-sectional perspective views of a multilayer ceramic capacitor 100 according to a fourth embodiment;

FIG. 16A and FIG. 16B are partial cross-sectional perspective views of a multilayer ceramic capacitor 100 according to a fifth embodiment;

FIG. 17 is an external view of a multilayer ceramic capacitor according to s sixth embodiment;

FIG. 18 is a cross-sectional view taken along a line A-A in FIG. 17;

FIG. 19 is a cross-sectional view taken along a line B-B in FIG. 17;

FIG. 20 is an enlarged cross-sectional view of a vicinity of an external electrode;

FIG. 21 illustrates a multilayer ceramic capacitor having a large number of stacked layers;

FIG. 22 illustrates a crack due to removing of binder;

FIG. 23 illustrates a manufacturing method of a multilayer ceramic capacitor;

FIG. 24 illustrates a stacking process;

FIG. 25 is a side view of a circuit board including a multilayer ceramic capacitor;

FIG. 26 is a partial plan view of a package;

FIG. 27 is a cross-sectional view of a package taken along a line D-D in FIG. 26;

FIG. 28 illustrates a crack at a corner portion near an external electrode;

FIG. 29 illustrates a multilayer ceramic capacitor according to a seventh embodiment;

FIG. 30 illustrates a dimension “e”;

FIG. 31 illustrates a stacking process;

FIG. 32 illustrates a multilayer ceramic capacitor according to an eighth embodiment; and

FIG. 33 illustrates a stacking process.

### DETAILED DESCRIPTION

In order to increase the capacity of ceramic electronic devices, progress has been made in making the layers thinner, increasing the number of layers, and reducing the cover layer and side margin (outer protective portion). However, if the area of the internal electrode layer or the number of layers is increased and the cover layer and side margin are made thinner, cracks may occur in the overlapping parts of the cover layer and side margin covered by the external electrode when the Cu external electrode is baked. In order to suppress this cracking, it is considered to suppress the diffusion of Cu (see, for example, Internal Publication No. 2014/175034). As a means of suppressing the diffusion of Cu, generally, a method of lowering the baking temperature by adjusting the components of the glass added to the conductive paste forming the external electrode (see, for example, Internal Publication No. 2014/175034) or adding a low-melting point metal such as Sn (see, for example, Japanese Patent Application Publication No. 2022-067608) is known.

However, if the baking temperature is excessively lowered to a level where cracks do not occur, there are problems such as a decrease in the density of the external electrode, making it difficult to ensure reliability, and a decrease in the adhesive strength between the external electrode and the ceramic body.

Furthermore, in order to increase the capacity of a multilayer ceramic capacitor, it is important to increase the total opposing area of the internal electrode layers. In order to increase the capacity without increasing the mounting area, it is possible to increase the number of stacked internal electrode layers (see, for example, Japanese Patent Application Publication No. 2014-212295). However, if the number of stacked layers is large, misalignment is more likely to occur during stacking, and it becomes difficult to cut the pre-fired multilayer structure perpendicular to the stacking direction.

Therefore, it is possible to increase the width of the internal electrode layers while suppressing the number of stacked layers. However, if the width of the internal electrode layers is large, there is a risk that the binder will not be sufficiently removed (Japanese Patent Application Publication No. 2011-134943). If the binder is not sufficiently removed, cracks may occur.

A description will be given of an embodiment with reference to the accompanying drawings.

### Embodiment

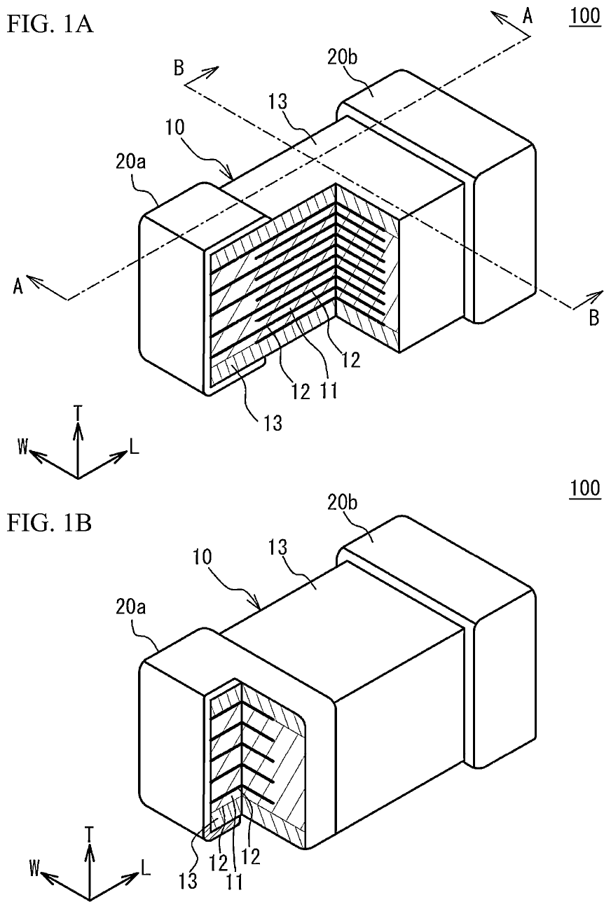

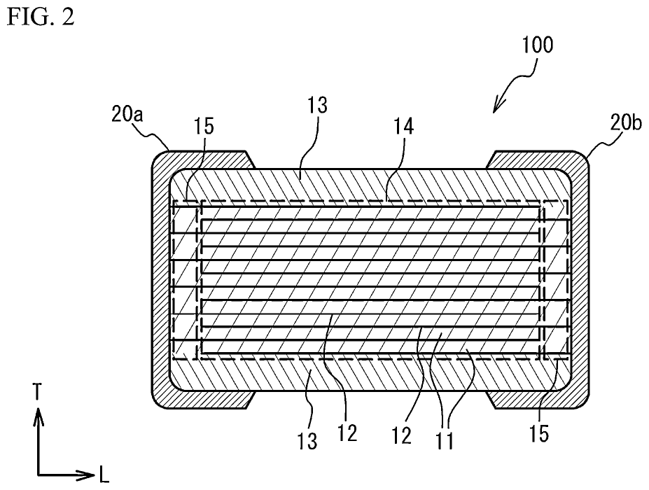

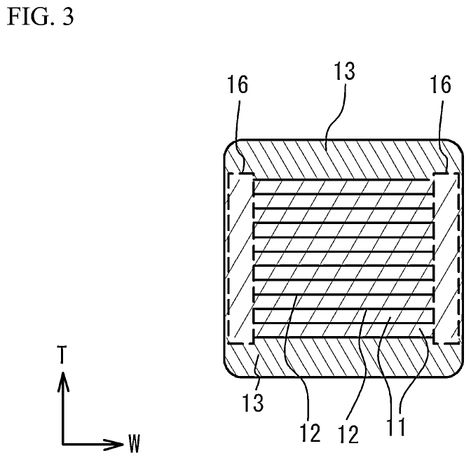

FIG. 1A and FIG. 1B illustrate a perspective view of a multilayer ceramic capacitor 100 in accordance with an embodiment, in which a cross section of a part of the multilayer ceramic capacitor 100 is illustrated. FIG. 2 illustrates a cross sectional view taken along a line A-A of FIG. 1A. FIG. 3 illustrates a cross sectional view taken along a line B-B of FIG. 1A. As illustrated in FIG. 1A and FIG. 1B, the multilayer ceramic capacitor 100 includes a multilayer chip 10 having a rectangular parallelepiped shape, and a pair of external electrodes 20a and 20b that are respectively provided at two end faces of the multilayer chip 10 facing each other. In four faces other than the two end faces of the multilayer chip 10, two faces other than an upper face and a lower face of the multilayer chip 10 in a stacking direction are referred to as side faces. The external electrodes 20a and 20b extend to the upper face, the lower face and the two side faces of the multilayer chip 10. However, the external electrodes 20a and 20b are spaced from each other.

In addition, in FIG. 1A to 3, the T direction (first direction) is the height direction of the multilayer ceramic capacitor 100 and is perpendicular to the direction in which the external electrodes 20a and 20b face each other (length direction: L direction). The W direction (second direction) is perpendicular to the T direction and the L direction. In this embodiment, the T direction corresponds to the stacking direction of the internal electrode layers 12 and is the direction in which the upper and lower faces of the multilayer chip 10 face each other. The W direction is the direction in which the two side faces of the multilayer chip 10 face each other. The L direction is the direction in which the two end faces of the multilayer chip 10 face each other.

If the height of the multilayer ceramic capacitor 100 in the T direction is height T₀, the width in the W direction is width W₀, and the length of the multilayer ceramic capacitor 100 in the L direction is length L₀, the multilayer ceramic capacitor 100 has a relationship of T₀=W₀. The height T₀, width W₀, and length L₀ are the maximum dimensions in the T direction, the W direction, and the L direction, respectively.

The multilayer chip 10 has a configuration in which dielectric layers 11 containing a ceramic material that functions as a dielectric and the internal electrode layers 12 of which a main component is a metal are alternately stacked. In other words, the multilayer chip 10 includes the plurality of internal electrode layers 12 facing each other, and the dielectric layers 11 sandwiched between the plurality of internal electrode layers 12. The edges of the internal electrode layers 12 are alternately exposed to the end face of the multilayer chip 10 on which the external electrode 20a is provided and the end face on which the external electrode 20b is provided. The internal electrode layer 12 connected to the external electrode 20a is not connected to the external electrode 20b, and the internal electrode layer 12 connected to the external electrode 20b is not connected to the external electrode 20a. As a result, each of the internal electrode layers 12 is alternately conductive to the external electrode 20a and the external electrode 20b. As a result, the multilayer ceramic capacitor 100 has a configuration in which the dielectric layers 11 are stacked through the internal electrode layers 12. In addition, in the multilayer structure of the dielectric layers 11 and the internal electrode layers 12, the internal electrode layers 12 are arranged on both outermost layers in the stacking direction, and the internal electrode layers 12 of the outermost layers are covered by cover layers 13. The cover layers 13 are mainly composed of a ceramic material. For example, the cover layers 13 may have the same composition as the dielectric layers 11 or may have a different composition. As long as the internal electrode layers 12 are exposed on two different faces and are electrically connected to different external electrodes, the configurations are not limited to those illustrated in FIG. 1 to FIG. 3

A main component of the dielectric layer 11 is a ceramic material having a perovskite structure expressed by a general formula ABO₃. The perovskite structure includes ABO_{3-α} having an off-stoichiometric composition. For example, the ceramic material is such as BaTiO₃ (barium titanate), CaZrO₃ (calcium zirconate), CaTiO₃ (calcium titanate), SrTiO₃ (strontium titanate), MgTiO₃ (magnesium titanate), Ba_{1-x-y}CaₓSr_{y}Ti_{1-z}Zr_{z}O₃ (0≤x≤1, 0≤y≤1, 0≤z≤1) having a perovskite structure. Ba_{1-x-y}CaₓSr_{y}Ti_{1-z}Zr_{z}O₃ may be barium strontium titanate, barium calcium titanate, barium zirconate, barium titanate zirconate, calcium titanate zirconate, barium calcium titanate zirconate or the like. For example, the dielectric layers 11 contain 90 at % or more of the main component ceramic. The average thickness of each of the dielectric layers 11 in the Z-axis direction is, for example, 0.5 μm or less, and preferably 0.3 μm or less. The average thickness of each of the dielectric layers 11 in the Z-axis direction can be measured by observing a cross section of the multilayer ceramic capacitor 100 with a SEM (scanning electron microscope), measuring the thickness at 10 points for each of 10 different dielectric layers 11, and deriving the average value of all the measurement points.

Additives may be added to the dielectric layer 11. As additives to the dielectric layer 11, an oxide of Mg (magnesium), Mn (manganese), Mo (molybdenum), vanadium (V), chromium (Cr), or a rare earth element (Y (yttrium), Sm (samarium), Eu (europium), Gd (gadolinium), Tb (terbium), Dy (dysprosium), Ho (holmium), Er (erbium), Tm (thulium) or Yb (ytterbium), or an oxide of Co (cobalt), Ni (nickel), Li (lithium), B (boron), Na (sodium), K (potassium) or Si (silicon), or a glass including cobalt, nickel, lithium, boron, sodium, potassium or silicon.

The thickness of each of the dielectric layers 11 in the stacking direction is, for example, 0.3 μm or more and 10 μm or less, or 0.4 μm or more and 8 μm or less, or 0.5 μm or more and 5 μm or less. The thickness of each of the dielectric layers 11 can be measured by exposing the cross section of the multilayer ceramic capacitor 100, for example, in FIG. 2, by mechanical polishing, and then obtaining the average value of the thickness at 10 points from an image taken by a microscope such as a scanning transmission electron microscope.

A main component of the internal electrode layer 12 is Ni. The thickness of each of the internal electrode layers 12 in the stacking direction is, for example, 0.1 μm or more and 2 μm or less. The thickness of each of the internal electrode layers 12 can be measured by exposing the cross section of the multilayer ceramic capacitor 100, for example, in FIG. 2, by mechanical polishing, and then obtaining the average value of the thickness at 10 points from an image taken by a microscope such as a scanning transmission electron microscope.

As illustrated in FIG. 2, a section, in which a set of the internal electrode layers 12 connected to the external electrode 20a face another set of the internal electrode layers 12 connected to the external electrode 20b, is a section generating electrical capacity in the multilayer ceramic capacitor 100. Accordingly, the section is referred to as a capacity section 14. That is, the capacity section 14 is a section in which the internal electrode layers next to each other being connected to different external electrodes face each other.

A section, in which the internal electrode layers 12 connected to the external electrode 20a face each other without sandwiching the internal electrode layer 12 connected to the external electrode 20b, is referred to as an end margin 15. A section, in which the internal electrode layers 12 connected to the external electrode 20b face each other without sandwiching the internal electrode layer 12 connected to the external electrode 20a is another end margin 15. That is, the end margin 15 is a section in which a set of the internal electrode layers 12 connected to one external electrode face each other without sandwiching the internal electrode layer 12 connected to the other external electrode. The end margins 15 are sections that do not generate electrical capacity in the multilayer ceramic capacitor 100. The end margin 15 may have the same composition as the dielectric layer 11 of the capacity section 14, or may have a different composition.

As illustrated in FIG. 3, a section of the multilayer chip 10 from the two sides thereof to the internal electrode layers 12 is referred to as a side margin 16. That is, the side margin 16 is a section covering edges of the stacked internal electrode layers 12 in the extension direction toward the two side faces. The side margin 16 does not generate electrical capacity. The side margin 16 may have the same composition as the dielectric layer 11 of the capacity section 14, or may have a different composition.

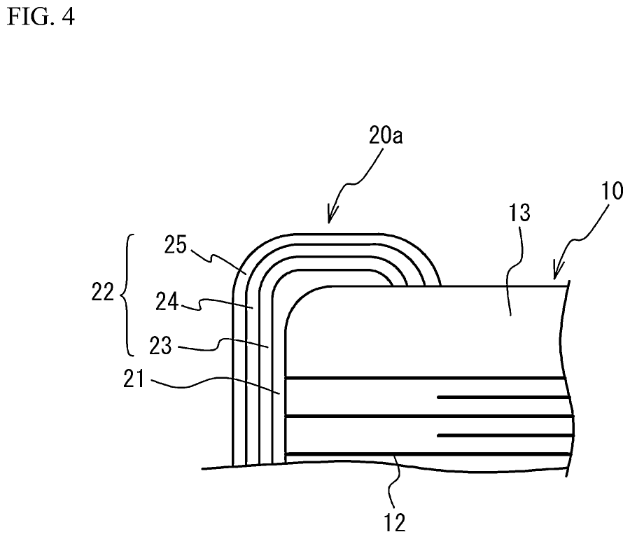

FIG. 4 is an enlarged cross-sectional view of the vicinity of the external electrode 20a. Hatching is omitted in FIG. 4. As illustrated in FIG. 4, the external electrode 20a has a structure in which a plated layer 22 is provided on a base layer 21. The base layer 21 is mainly composed of Cu. The base layer 21 may also contain a glass component. The plated layer 22 is mainly composed of a metal such as Cu, Ni, aluminum (Al), zinc (Zn), Sn, or an alloy of two or more of these. The plated layer 22 may be a plated layer of a single metal component, or may be a plurality of plating layers of different metal components. For example, the plated layer 22 has a structure in which a first plated layer 23, a second plated layer 24, and a third plated layer 25 are formed in this order from the base layer 21 side. The first plated layer 23 is, for example, a Sn plated layer. The second plated layer 24 is, for example, a Ni plated layer. The third plated layer 25 is, for example, a Sn plated layer. Although FIG. 4 illustrates the external electrode 20a, the external electrode 20b also has a similar multilayer structure.

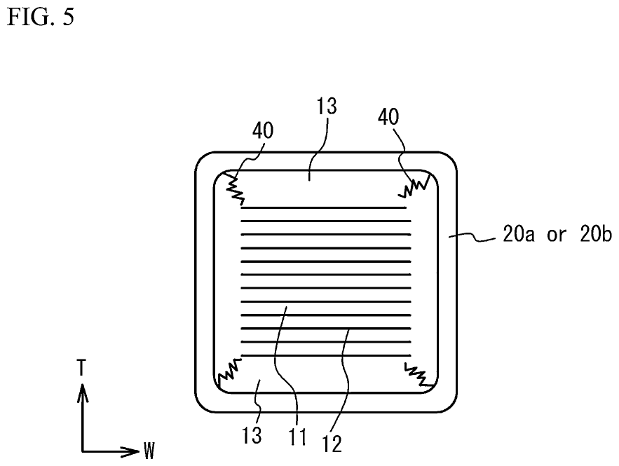

In order to increase the capacity of multilayer ceramic capacitors, progress is being made in making the layers thinner, increasing the number of layers, and reducing the cover layer and side margin. However, if the area of the internal electrode layer and the number of layers are increased and the cover layer and side margin are made thinner, a crack 40 as illustrated in FIG. 5 may occur in the part where the cover layer and the side margin overlap (corner part near the external electrode) covered by the external electrode when the external electrode is baked.

This occurs based on the following mechanism. If the internal electrode layer 12 and the base layer 21 react when the base layer 21 is baked, Cu, which is a metal component of the base layer 21, diffuses to the Ni side of the internal electrode layer 12, and the internal electrode layer 12 expands. This expansion of the internal electrode layer 12 generates outward stress in the cover layer 13 and the side margin 16, causing cracks. In order to suppress this crack, it is considered to suppress the diffusion of Cu. As a means for suppressing the diffusion of Cu, for example, the baking temperature can be lowered by adjusting the components of the glass added to the conductive paste for forming the base layer 21 or by adding a low melting point metal such as Sn.

However, if the baking temperature is lowered to a level where cracks do not occur, problems such as the density of the base layer 21 decreasing, making it difficult to ensure reliability, or the adhesive strength between the base layer 21 and the multilayer chip 10 decreasing may occur. In addition, if the cracks 40 occur in the parts covered by the external electrodes 20a and 20b, it is a major problem that the cracks 40 cannot be confirmed from the outside.

Therefore, the multilayer ceramic capacitor 100 according to this embodiment has a configuration that can suppress the occurrence of cracks due to the diffusion of Cu without excessively lowering the baking temperature.

First, the internal electrode layer 12 and the base layer 21 contain a low melting point metal with a lower melting point than Cu, which is the main component metal of the base layer 21. The low melting point metal is not particularly limited as long as it has a melting point lower than that of Cu, and examples thereof is such as Ga (gallium), In (indium), Sn, Bi (bismuth), Zn, or Al.

In the internal electrode layer 12, the low melting point metal may be alloyed with Ni, which is the main component of the internal electrode layer 12, or may be disposed as a single metal. For example, the low melting point metal may be uniformly dispersed and disposed in the internal electrode layer 12, or may segregate at the interface between the internal electrode layer 12 and the dielectric layer 11.

In the base layer 21, the low melting point metal may be alloyed with Cu, which is the main component of the base layer 21, or may be disposed as a single metal. For example, the low melting point metal may be uniformly dispersed and disposed in the base layer 21, or may segregate at the interface between the base layer 21 and the multilayer chip 10.

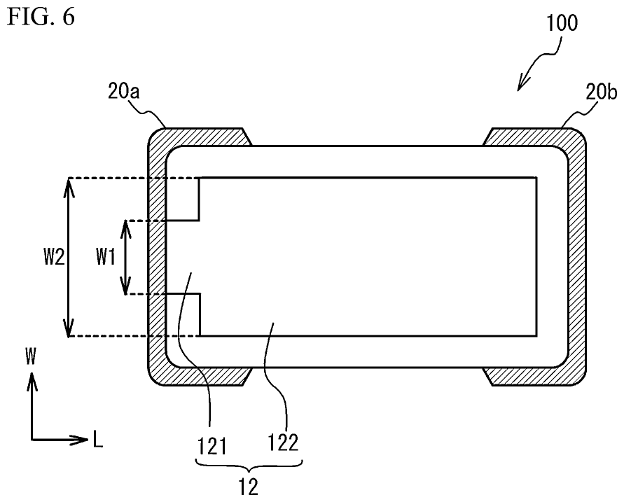

In addition, the dimensions of each of the internal electrode layers 12 in the in-plane direction are made to vary. Specifically, as illustrated in FIG. 6, the internal electrode layer 12 connected to the external electrode 20a has a first section 121 (connection portion) connected to the external electrode 20a in a section corresponding to the end margin 15 and having a dimension W1 in the W direction, and a second section 122 in a section corresponding to the capacity section 14 and having a dimension W2 in the W direction. The dimension W1 is smaller than the dimension W2. In the W direction, the first section 121 is located inside the second section 122. The internal electrode layer 12 connected to the external electrode 20b also has the first section 121 having the dimension W1 and the second section 122 having the dimension W2. For example, the center of the first section 121 in the W direction coincides with the center of the second section 122 in the W direction.

With this configuration, even if the base layer 21 containing the low melting point metal such as Ga, In, Sn, Bi, Zn, or Al is used to prevent deterioration of insulation resistance due to hydrogen generated in the plating process, and the internal electrode layer 12 containing the low melting point metal such as Ga, In, Sn, Bi, Zn, or Al is used to change the potential barrier at the interface with the dielectric layer 11 and improve the high temperature load life, the movement distance from the base layer 21 to the internal electrode layer 12 is long at the corners, so diffusion from the base layer 21 to the internal electrode layer 12 is suppressed. This suppresses the occurrence of the cracks 40. From the above, it is possible to suppress the occurrence of cracks without excessively lowering the baking temperature. As a result, the denseness of the base layer 21 can be ensured.

If W1/W2 is small, the connectivity between the external electrodes 20a, 20b and the internal electrode layer 12 may decrease, making it difficult to obtain good electrical continuity, so it is preferable to set a lower limit for W1/W2. On the other hand, if W1/W2 is large, the movement distance from the external electrodes 20a, 20b to the internal electrode layer 12 may not be long enough. Therefore, it is preferable to set an upper limit for W1/W2. For the above reasons, W1/W2 is preferably ½ or more, and more preferably ⅔ or more. Furthermore, W1/W2 is preferably ⅘ or less, and more preferably ¾ or less.

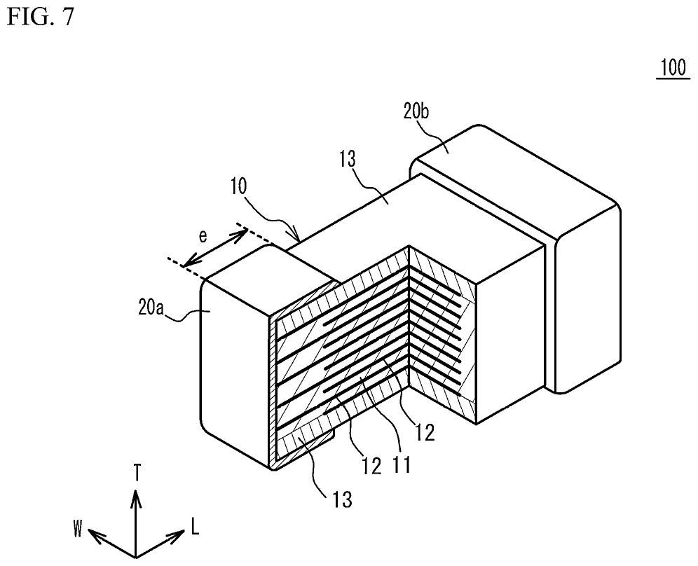

Here, as illustrated in FIG. 7, the dimension of the external electrodes 20a, 20b extending in the L direction from both end faces of the multilayer chip 10 is referred to as dimension “e”. From the viewpoint of suppressing the cracks 40 at the corners, the dimension of the first section 121 in the L direction is preferably ⅓ or more of the dimension “e”, and more preferably ½ or more.

If a sufficient amount of the low melting point metal is not added to the base layer 21, there is a risk that it will not be possible to prevent deterioration of the insulation resistance due to hydrogen generated in the plating process. Therefore, it is preferable to set a lower limit for the concentration of the low melting point metal added to the base layer 21. In this embodiment, the concentration of the low melting point metal added is preferably 1 at % or more, more preferably 3 at % or more, and even more preferably 5 at % or more. The concentration of the low melting point metal added refers to the amount of low melting point metal added (at %) when Cu is 100 at % in the entire base layer 21. When multiple types of low melting point metals are included, the concentration of the low melting point metal is the total amount of the multiple types of the low melting point metals.

On the other hand, if the amount of the low melting point metal added in the base layer 21 is large, there is a risk that the diffusion of Cu into the internal electrode layer 12 may not be sufficiently suppressed. Therefore, it is preferable to set an upper limit on the concentration of the low melting point metal. In this embodiment, the concentration of the low melting point metal is preferably 20 at % or less, more preferably 15 at % or less, and even more preferably 10 at % or less.

If a sufficient amount of the low melting point metal is not added to the internal electrode layer 12, there is a risk that the potential barrier for improving the high temperature load life may not be necessarily changed. Therefore, it is preferable to set a lower limit on the concentration of the low melting point metal added to the internal electrode layer 12. In this embodiment, the concentration of the low melting point metal is preferably 0.1 at % or more, more preferably 0.3 at % or more, and even more preferably 0.5 at % or more. The concentration of the low melting point metal is the amount (at %) of the low melting point metal added when Ni is 100 at % in the entire internal electrode layer 12 between the two adjacent dielectric layers 11. When multiple types of the low melting point metals are included, the concentration of the low melting point metal added is the total amount of the multiple types of low melting point metals.

On the other hand, if the amount of the low melting point metal added in the internal electrode layer 12 is large, there is a risk of causing the internal electrode to become spherical due to oversintering and abnormal grain growth of the dielectric layer. Therefore, it is preferable to set an upper limit on the concentration of the low melting point metal added in the internal electrode layer 12. In this embodiment, the concentration of the low melting point metal added is preferably 10 at % or less, more preferably 5 at % or less, and even more preferably 2 at % or less.

In the T direction, the stacking density of the internal electrode layers 12 is, for example, 500 layers/mm or more, 750 layers/mm or more, or 1000 layers/mm or more and 1500 layers/mm or less.

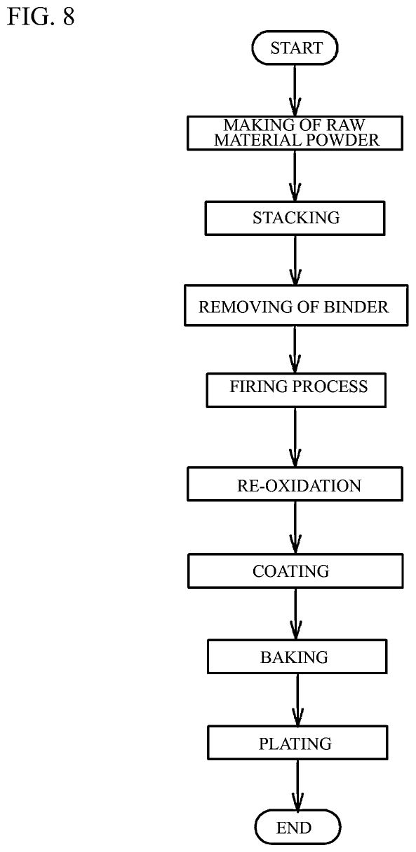

Next, a description will be given of a manufacturing method of the multilayer ceramic capacitors 100 in accordance with the first embodiment. FIG. 8 illustrates a manufacturing method of the multilayer ceramic capacitor 100.

(Making process of raw material powder) A dielectric material for forming the dielectric layer 11 is prepared. The dielectric material includes the main component ceramic of the dielectric layer 11. Generally, an A site element and a B site element are included in the dielectric layer 11 in a sintered phase of grains of ABO₃. For example, barium titanate is tetragonal compound having a perovskite structure and has a high dielectric constant. Generally, barium titanate is obtained by reacting a titanium material such as titanium dioxide with a barium material such as barium carbonate and synthesizing barium titanate. Various methods can be used as a synthesizing method of the ceramic structuring the dielectric layer 11. For example, a solid-phase method, a sol-gel method, a hydrothermal method or the like can be used. The embodiments may use any of these methods.

An additive compound may be added to the resulting ceramic powder, in accordance with purposes. The additive compound may be an oxide of magnesium, manganese, molybdenum, vanadium, chromium, a rare earth element (yttrium, samarium, europium, gadolinium, terbium, dysprosium, holmium, erbium, thulium or ytterbium), or an oxide containing cobalt, nickel, lithium, boron, sodium, potassium or silicon, or glasses containing cobalt, nickel, lithium, boron, sodium, potassium or silicon.

For example, the resulting ceramic raw material powder is wet-blended with additives and is dried and crushed. Thus, a ceramic material is obtained. For example, the particle diameter may be adjusted by crushing the resulting ceramic material as needed. Alternatively, the grain diameter of the resulting ceramic powder may be adjusted by combining the crushing and classifying. With the processes, a dielectric material is obtained.

(Stacking process) Next, a binder such as polyvinyl butyral (PVB) resin, an organic solvent such as ethanol or toluene, and a plasticizer are added to the resulting dielectric material and wet-blended. With use of the resulting slurry, a dielectric green sheet ius formed on a base material by, for example, a die coater method or a doctor blade method, and then dried. The base material is, for example, PET (polyethylene terephthalate) film.

Next, an internal electrode pattern is formed on the dielectric green sheet. The dielectric green sheet on which the internal electrode pattern is formed is a stack unit. Ni powder including the low melting temperature metal of which a melting point is lower than that of Cu is used as the internal electrode pattern. The forming method of the internal electrode pattern may be such as printing, sputtering, or vapor deposition.

(Crimping process) Next, the dielectric green sheets are peeled from the base materials. The stack units are stacked. Next, a predetermined number of cover sheets (for example, 2 to 10 layers) are stacked on the top and bottom of the multilayer structure obtained by stacking the stack units, and are thermally crimped. The cover sheet can be formed by the same method as that of the dielectric green sheet.

(Removing process of binder) The binder is removed from the ceramic multilayer structure in N₂ atmosphere. The thermal treatment temperature is approximately 250 degrees C. to 700 degrees C.

(Firing process) The resulting ceramic multilayer structure is fired for 10 μminutes to 2 hours in a reductive atmosphere having an oxygen partial pressure of 10⁻¹ to 10⁻⁸ atm in a temperature range of 1100 degrees C. to 1300 degrees C. Thus, the multilayer chip 10 is obtained.

(Re-oxidizing process) A re-oxidation treatment process may be performed in N₂ gas at 600° C. to 1000° C.

(Coating process) Next, a metal paste that will become the base layer 21 is coated on the first side of the multilayer structure by a dipping method or the like. This metal paste contains glass components such as glass frit, as well as the low melting point metal that has a lower melting point than Cu.

(Baking process) Next, the metal paste is baked at a temperature of about 700° C. to 900° C. to form the base layer 21.

(Plating process) After that, a metal coating of copper, nickel, tin, or the like may be applied to the base layer 21 by plating. For example, the first plated layer 23, the second plated layer 24, and the third plated layer 25 are formed in this order on the base layer 21. This completes the multilayer ceramic capacitor 100.

According to the manufacturing method according to this embodiment, the movement distance from the base layer 21 to the internal electrode layer 12 at the corners is long, so diffusion from the base layer 21 to the internal electrode layer 12 is suppressed. This suppresses the occurrence of the cracks 40. From the above, it is possible to suppress the occurrence of cracks without excessively lowering the baking temperature. As a result, it is possible to ensure the denseness of the base layer 21.

Note that in the above manufacturing method, the base layer 21 is baked after the multilayer chip 10 is fired, but this is not limited to this. For example, the base layer 21 may be fired at the same time as the multilayer chip 10 is fired.

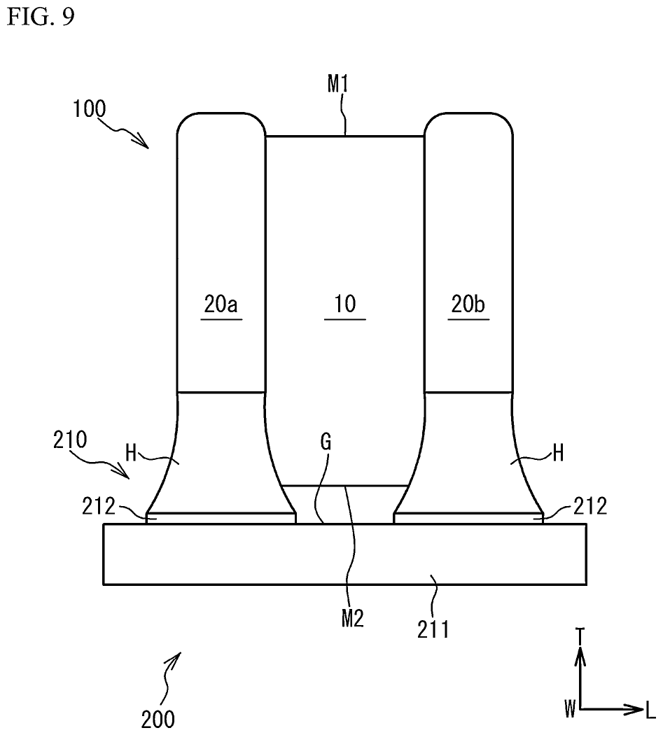

Here, the mounting of the multilayer ceramic capacitor 100 will be described. FIG. 9 is a side view of a circuit board 200 including the multilayer ceramic capacitor 100. The circuit board 200 has a mounting board 210 on which the multilayer ceramic capacitor 100 is mounted.

The mounting board 210 has a base substrate 211 that extends along the planes of the L and W directions and has a mounting surface G perpendicular to the T direction, and a pair of connection electrodes 212 provided on the mounting surface G.

On the circuit board 200, the external electrodes 20a and 20b of the multilayer ceramic capacitor 100 are connected to the pair of connection electrodes 212 of the mounting board 210 via a solder H. As a result, on the circuit board 200, the multilayer ceramic capacitor 100 is fixed to the mounting board 210 and electrically connected.

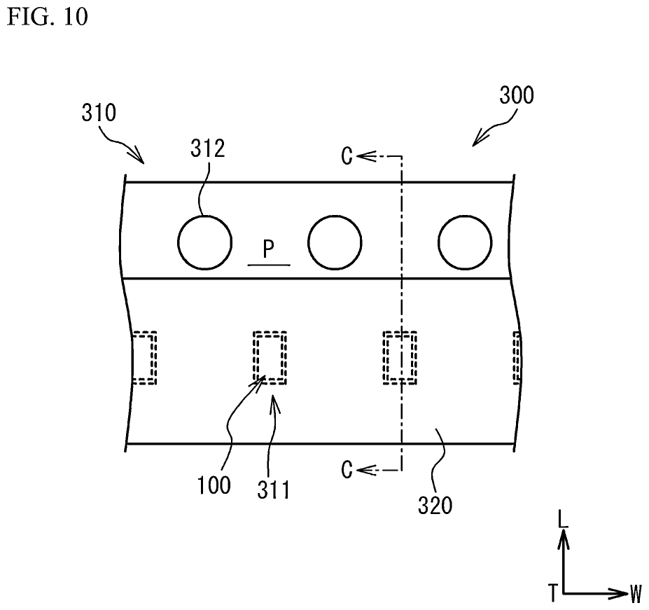

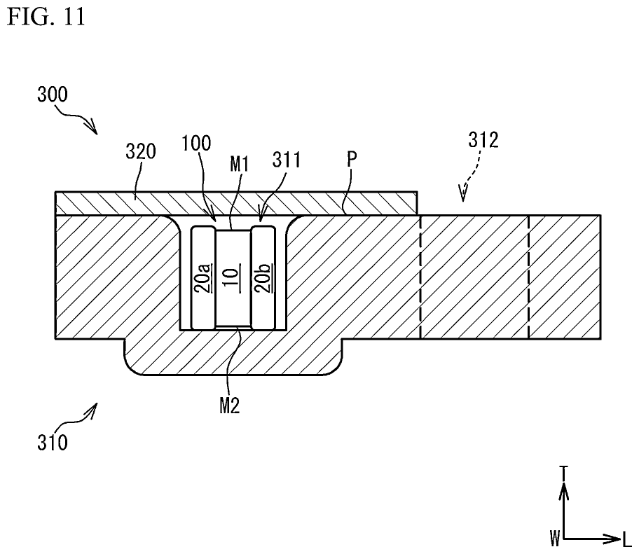

When mounting the multilayer ceramic capacitor 100 on the mounting board 210, the multilayer ceramic capacitor 100 is prepared in a packaged state as a package 300. FIG. 10 and FIG. 11 are diagrams illustrating the package 300. FIG. 10 is a partial plan view of the package 300. FIG. 11 is a cross-sectional view of the package 300 taken along a line C-C in FIG. 10.

The package 300 has the multilayer ceramic capacitor 100, a carrier tape 310, and a top tape 320. The carrier tape 310 is configured as a long tape extending in the W direction. The carrier tape 310 has a plurality of recesses 311 arranged at intervals in the W direction, each of which accommodates each of the multilayer ceramic capacitors 100.

The carrier tape 310 has a seal surface P, which is an upward surface perpendicular to the T direction, and the plurality of recesses 311 are recessed downward in the T direction from the seal surface P. In other words, the carrier tape 310 is configured so that the multilayer ceramic capacitors 100 in the plurality of recesses 311 can be removed from the seal surface P side.

The carrier tape 310 has a plurality of feed holes 312 that penetrate in the T direction and are arranged at intervals in the W direction at positions offset in the L direction from the row of the plurality of recesses 311. The feed holes 312 are configured as engagement holes used by the tape transport mechanism to transport the carrier tape 310 in the W direction.

In the package 300, the top tape 320 is attached to the seal surface P of the carrier tape 310 along the row of the plurality of recesses 311, and the plurality of recesses 311 containing the plurality of multilayer ceramic capacitors 100 are collectively covered by the top tape 320.

As a result, the plurality of multilayer ceramic capacitors 100 are held in the plurality of recesses 311.

As illustrated in FIG. 11, in the multilayer ceramic capacitor 100 in the recess 311 of the carrier tape 310, a first main surface M1 of the multilayer chip 10 facing upward in the T direction faces the top tape 320. Also, a second main surface M2 of the multilayer chip 10 facing downward in the T direction faces the bottom surface of the recess 311.

When mounting the multilayer ceramic capacitor 100 packaged as the package 300, the top tape 320 is peeled off from the seal surface P of the carrier tape 310 along the W direction.

As a result, in the package 300, the plurality of recesses 311 containing the plurality of multilayer ceramic capacitors 100 can be sequentially opened upward in the T direction.

The multilayer ceramic capacitor 100 housed in the opened recess 311 is removed with the first main surface M1 of the multilayer chip 10 facing upward in the T direction being sucked onto the tip of the suction nozzle of the mounting device. The mounting device moves the suction nozzle to move the multilayer ceramic capacitor 100 onto the mounting surface G of the mounting board 210.

Then, the mounting device releases the suction nozzle from the first main surface M1 of the multilayer chip 10 with the second main surface M2 of the multilayer chip 10 facing the mounting surface G and the external electrodes 20a and 20b aligned onto the pair of connection electrodes 212 to which the solder paste has been applied. Thus, the multilayer ceramic capacitor 100 is placed on the mounting surface G.

Then, the solder paste is melted and hardened using a reflow oven or the like for the mounting board 210 on which the multilayer ceramic capacitor 100 has been placed on the mounting surface G. As a result, the external electrodes 20a and 20b are connected to the pair of connection electrodes 212 of the mounting board 210 via the solder H, thereby obtaining the circuit board 200 illustrated in FIG. 9.

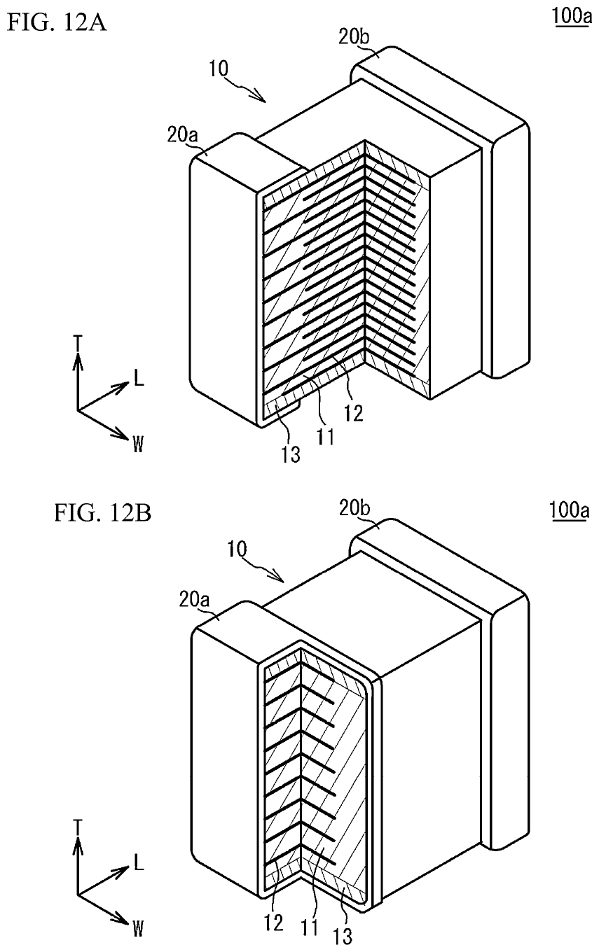

(Second embodiment) FIG. 12A and FIG. 12B are partial cross-sectional perspective views of a multilayer ceramic capacitor 100a according to a second embodiment. The multilayer ceramic capacitor 100a differs from the multilayer ceramic capacitor 100 according to the first embodiment in the ratio of T₀/W₀. In this embodiment, T₀/W₀ is 1.3 or more. In this configuration, the number of layers of the internal electrode layers 12 can be increased, and therefore the electrostatic capacity can be increased. From the viewpoint of increasing the electrostatic capacity, it is preferable that T₀/W₀ is 1.5 or more.

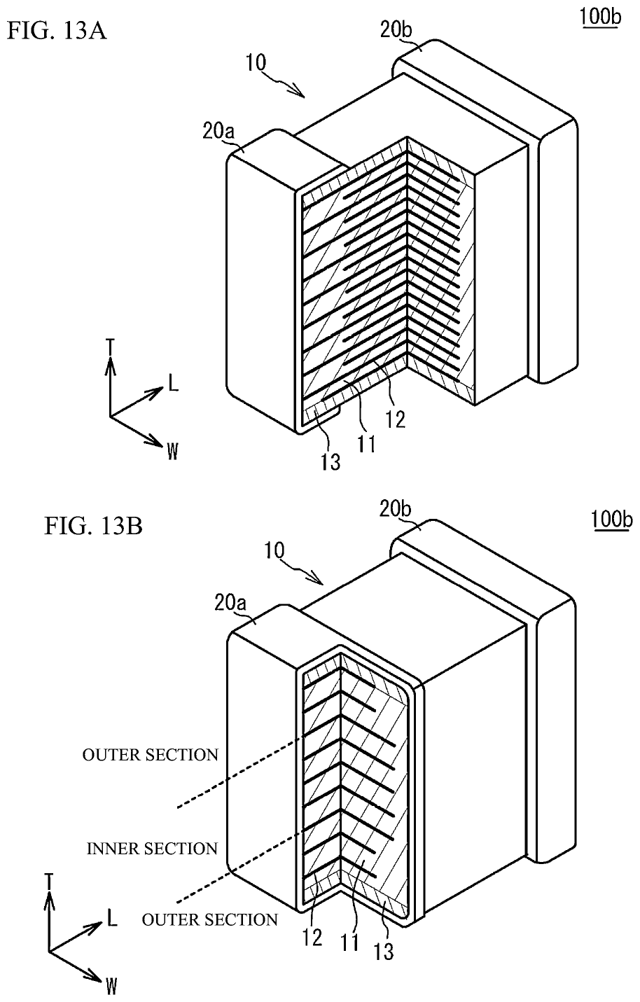

(Third embodiment) FIG. 13A and FIG. 13B are partial cross-sectional perspective views of a multilayer ceramic capacitor 100b according to a third embodiment. The multilayer ceramic capacitor 100b differs from the multilayer ceramic capacitor 100 according to the first embodiment in that not all of the internal electrode layers 12 have the first section 121 and the second section 122, but some of the internal electrode layers 12 have the first section 121 and the second section 122. For example, as illustrated in FIG. 13A and FIG. 13B, one or more internal electrode layers 12 have the first section 121 and the second section 122 from the outermost internal electrode layer 12 toward the inside. The internal electrode layer 12 having the first section 121 and the second section 122 is referred to as the internal electrode layer 12 in an outer section. The internal electrode layer 12 that is located inside the internal electrode layer 12 in the outer section and has a substantially constant dimension in the W direction is referred to as the internal electrode layer 12 in an inner section.

From the viewpoint of suppressing diffusion from the external electrodes 20a and 20b to the internal electrode layers 12, it is preferable that the number of layers of the internal electrode layers 12 in the outer section is 10% or more of the total number of layers, and it is more preferable that the number of layers of the internal electrode layers 12 in the outer section is 25% or more. On the other hand, from the viewpoint of reducing poor connection between the external electrodes 20a, 20b and the internal electrode layers 12, it is preferable that the number of layers of the internal electrode layers 12 in the outer section is 50% or less of the total number of layers, and it is more preferable that the number of layers of the internal electrode layers 12 in the outer section is 40% or less.

It is preferable that the number of layers of the internal electrode layers 12 in the outer section on one side of the internal electrode layers 12 in the inner section in the T direction is the same as the number of layers of the internal electrode layers 12 in the outer section on the other side of the T direction.

Note that the electrostatic capacity can be increased by increasing the number of layers of the internal electrode layers 12. From the viewpoint of increasing the electrostatic capacity, T₀/W₀ is preferably 1.3 or more, and more preferably 1.5 or more.

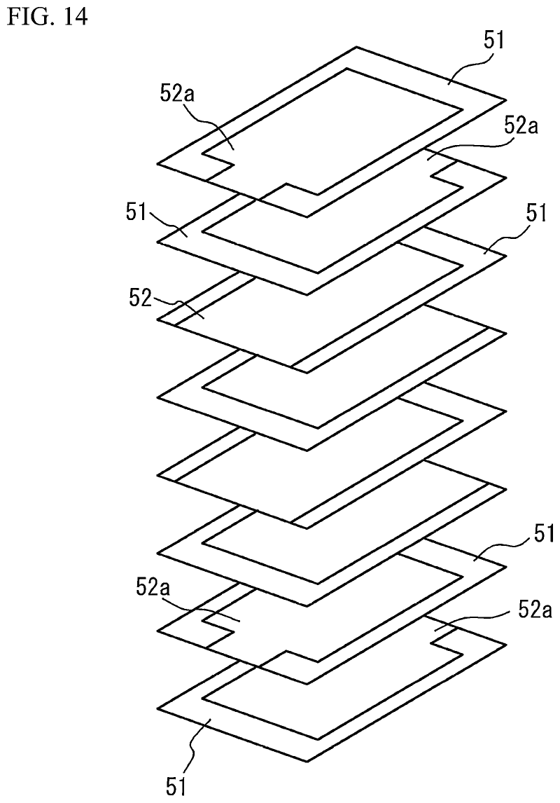

The multilayer ceramic capacitor 100b according to this embodiment can be obtained by stacking the dielectric green sheet 51 on which an internal electrode pattern 52a having the dimensions W1 and W2 is formed, and the dielectric green sheet 51 on which the internal electrode pattern 52 having a constant dimension in the W direction is formed, as illustrated in FIG. 14.

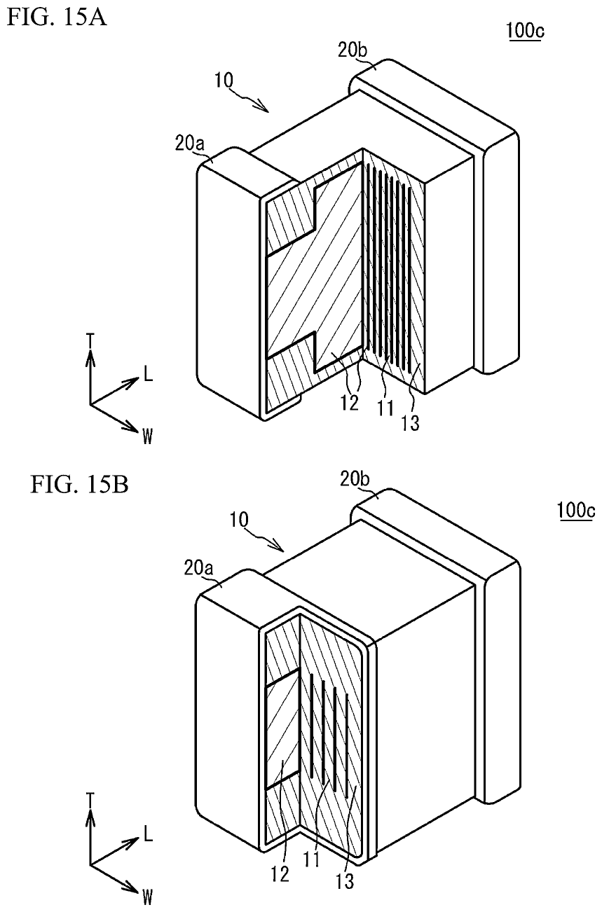

(Fourth embodiment) FIG. 15A and FIG. 15B are partial cross-sectional perspective views of a multilayer ceramic capacitor 100c according to the fourth embodiment. The multilayer ceramic capacitor 100c differs from the multilayer ceramic capacitor 100 according to the first embodiment in the stacking direction of the internal electrode layers 12. In this embodiment, the W direction corresponds to the stacking direction of the internal electrode layers 12, and is the direction in which the upper face and the lower face of the multilayer chip 10 face each other. The T direction is the direction in which the two side faces of the multilayer chip 10 face each other. The L direction is the direction in which the two end faces of the multilayer chip 10 face each other. Therefore, in this embodiment, the dimension W1 in the first embodiment can be read as the dimension Ti in the T direction, and the dimension W₂ can be read as the dimension T₂ in the T direction.

When the multilayer ceramic capacitor 100c is mounted on the mounting board 210, one of the two sides of the multilayer ceramic capacitor 100c faces the mounting board 210.

In the multilayer ceramic capacitor 100c, it is known, when the circuit board 200 is driven and a voltage is applied to the external electrodes 20a and 20b via the connection electrodes 212 of the mounting board 210, electrostriction occurs in the multilayer chip 10 due to the piezoelectric effect. The electrostriction occurring in the multilayer chip 10 causes relatively large deformation in the stacking direction of the internal electrode layers 12.

In the circuit board 200, repeated electrostriction occurs in the multilayer ceramic capacitor 100c to which an AC voltage is applied, which may cause vibration in the thickness direction of the substrate 211 of the mounting board 210. In the circuit board 200, when the vibration occurring in the substrate 211 becomes large, noise may be generated from the substrate 211, a phenomenon known as “ringing”.

However, in the multilayer ceramic capacitor 100c according to this embodiment, the stacking direction of the internal electrode layers 12 is the in-plane direction of the substrate 211, so that vibration in the thickness direction is unlikely to occur in the substrate 211 due to electrostriction of the multilayer chip 10. Also, in the multilayer ceramic capacitor 100c, the number of the internal electrode layers 12 is small, and the amount of deformation due to electrostriction is kept small, so that even if vibration occurs in the substrate 211, it is unlikely to be large enough to generate noise.

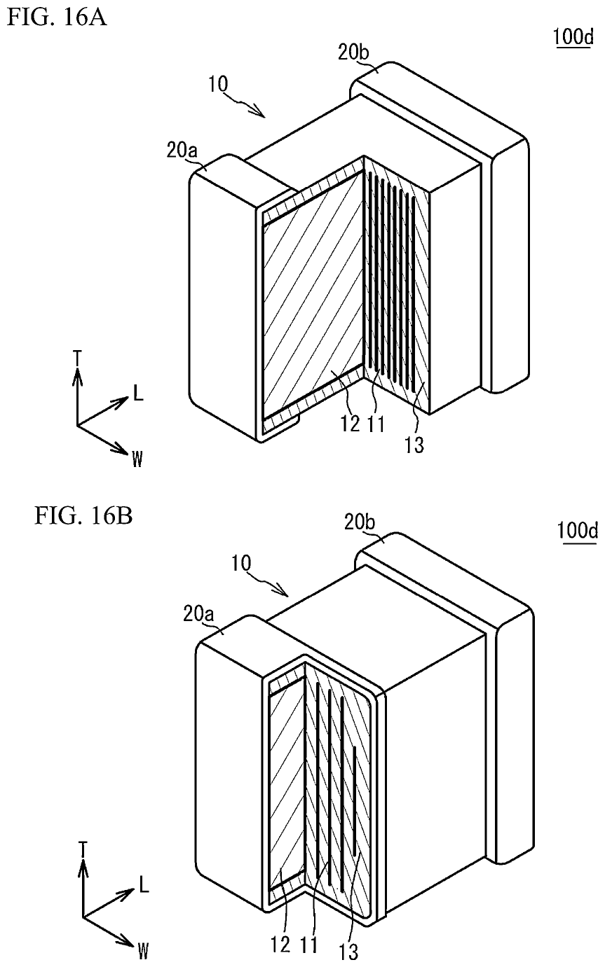

(Fifth embodiment) FIG. 16A and FIG. 16B are partial cross-sectional perspective views of a multilayer ceramic capacitor 100d according to the fifth embodiment. The multilayer ceramic capacitor 100d differs from the multilayer ceramic capacitor 100c according to the fourth embodiment in that not all of the internal electrode layers 12 have the first section 121 and the second section 122, but some of the internal electrode layers 12 have the first section 121 and the second section 122. For example, as illustrated in FIG. 13A and FIG. 13B, one or more internal electrode layers 12 have the first section 121 and the second section 122 from the outermost internal electrode layer 12 toward the inside. The internal electrode layer 12 having the first section 121 and the second section 122 is referred to as the internal electrode layer 12 in the outer section. The internal electrode layer 12 that is located inside the internal electrode layer 12 in the outer section and has a substantially constant dimension in the T direction is referred to as the internal electrode layer 12 in the inner section.

From the viewpoint of suppressing diffusion from the external electrodes 20a and 20b to the internal electrode layers 12, it is preferable that the number of layers of the internal electrode layers 12 in the outer section is 10% or more of the total number of layers, and it is more preferable that the number of layers of the internal electrode layers 12 in the outer section is 25% or more. On the other hand, from the viewpoint of reducing poor connection between the external electrodes 20a, 20b and the internal electrode layers 12, it is preferable that the number of layers of the internal electrode layers 12 in the outer section is 50% or less of the total number of layers, and it is more preferable that the number of layers of the internal electrode layers 12 in the outer section is 40% or less.

It is preferable that the number of layers of the internal electrode layers 12 in the outer section on one side in the W direction of the internal electrode layers 12 in the inner section is the same as the number of layers of the internal electrode layers 12 in the outer section on the other side in the W direction.

When the multilayer ceramic capacitor 100d is mounted on the mounting board 210, one of the two side faces of the multilayer ceramic capacitor 100d faces the mounting board 210.

It is known that in the multilayer ceramic capacitor 100d, when the circuit board 200 is driven and a voltage is applied to the external electrodes 20a and 20b via the connection electrodes 212 of the mounting board 210, electrostriction occurs in the multilayer chip 10 due to the piezoelectric effect. The electrostriction occurring in the multilayer chip 10 causes relatively large deformation in the stacking direction of the internal electrode layers 12.

In the circuit board 200, repeated electrostriction occurs in the multilayer ceramic capacitor 100d to which an AC voltage is applied, which may cause vibration in the thickness direction of the substrate 211 of the mounting board 210. In the circuit board 200, when the vibration occurring in the substrate 211 becomes large, noise may be generated from the substrate 211, a phenomenon known as “ringing”.

However, in the multilayer ceramic capacitor 100d according to this embodiment, the stacking direction of the internal electrode layers 12 is the in-plane direction of the substrate 211, so that vibration in the thickness direction of the substrate 211 is unlikely to occur due to electrostriction of the multilayer chip 10. Furthermore, in the multilayer ceramic capacitor 100d, the number of the internal electrode layers 12 is small, and the amount of deformation due to electrostriction is kept small, so that even if vibration occurs in the substrate 211, it is unlikely to be large enough to generate noise.

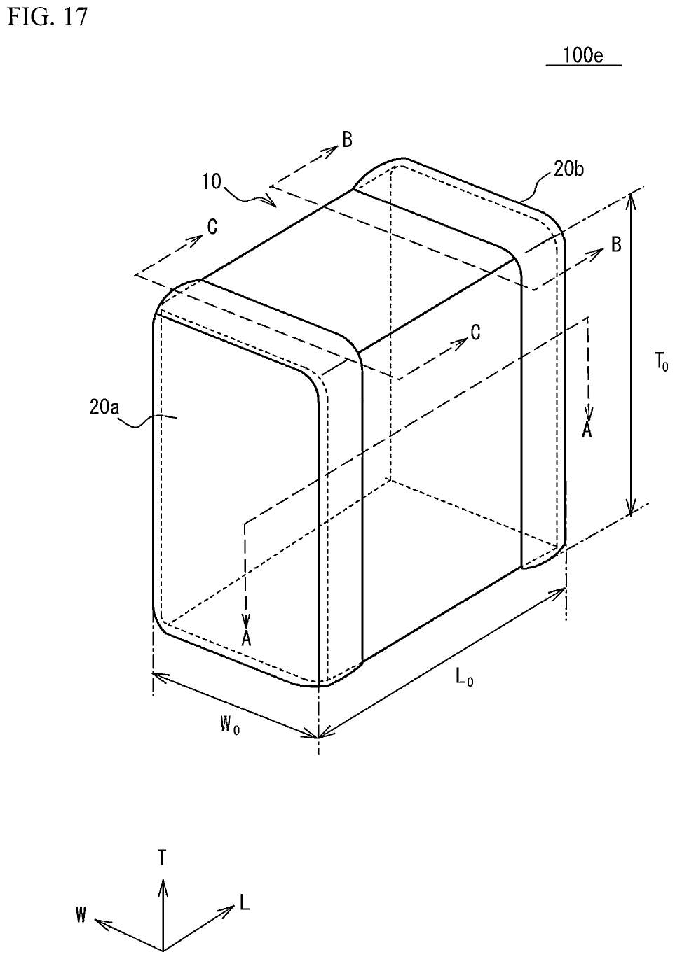

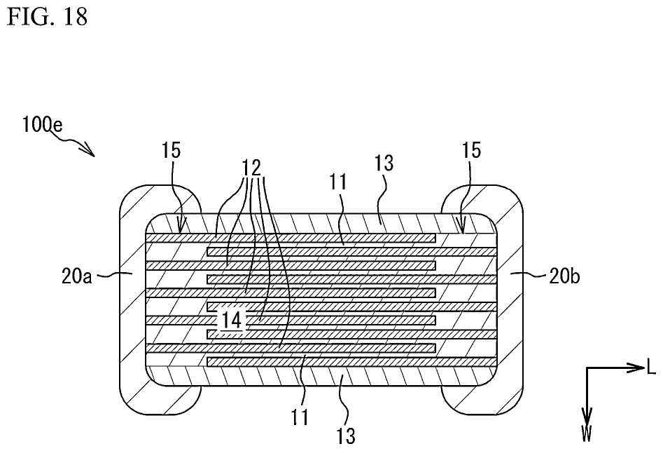

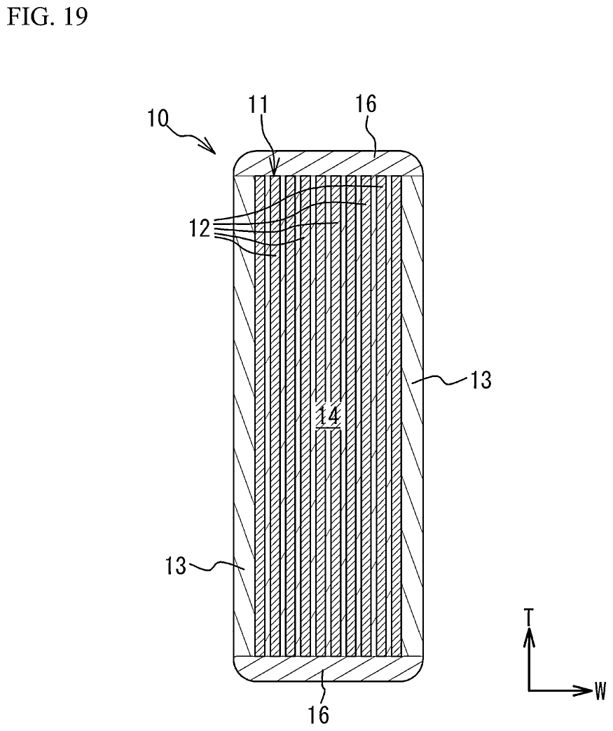

(Sixth embodiment) FIG. 17 is an external view of a multilayer ceramic capacitor 100e according to the sixth embodiment. FIG. 18 is a cross-sectional view taken along a line A-A in FIG. 17. FIG. 19 is a cross-sectional view taken along a line B-B in FIG. 17. As illustrated in FIG. 17 to FIG. 19, the multilayer ceramic capacitor 100e includes the multilayer chip 10 having a substantially rectangular parallelepiped shape and the external electrodes 20a, 20b provided on two opposing end faces of the multilayer chip 10. Of the four faces of the multilayer chip 10 other than the two end faces, the two faces at both ends in the stacking direction are referred to as side faces. In the multilayer chip 10, the two faces other than the two end faces and the two side faces are referred to as the upper face and the lower face. The lower face functions as a mounting face and faces the mounting board when the multilayer ceramic capacitor 100e is mounted on the mounting board. The external electrodes 20a and 20b extend to the upper face, the lower face and the two side faces of the multilayer chip 10. However, the external electrodes 20a and 20b are spaced apart from each other.

In addition, in FIG. 17 to FIG. 19, the T direction (first direction) is the height direction of the multilayer ceramic capacitor 100e, and is the direction in which the upper face and the lower face of the multilayer chip 10 face each other. The W direction (second direction) is the stacking direction of the dielectric layers 11 and the internal electrode layers 12. The L direction (third direction) is the direction in which the two end faces of the multilayer chip 10 face each other, and in which the external electrodes 20a and 20b face each other. The L direction, the W direction, and the T direction are orthogonal to each other.

The multilayer chip 10 has a configuration in which the dielectric layers 11 containing a ceramic material that functions as a dielectric and the internal electrode layers 12 of which a main component is a metal are alternately stacked. In other words, the multilayer chip 10 includes the plurality of internal electrode layers 12 facing each other, and the dielectric layers 11 sandwiched between the plurality of internal electrode layers 12. The edges of the internal electrode layers 12 are alternately exposed to the end face of the multilayer chip 10 on which the external electrode 20a is provided and the end face on which the external electrode 20b is provided. The internal electrode layer 12 connected to the external electrode 20a is not connected to the external electrode 20b, and the internal electrode layer 12 connected to the external electrode 20b is not connected to the external electrode 20a. As a result, each of the internal electrode layers 12 is alternately conductive to the external electrode 20a and the external electrode 20b. As a result, the multilayer ceramic capacitor 100 has a configuration in which the dielectric layers 11 are stacked through the internal electrode layers 12. In addition, in the multilayer structure of the dielectric layers 11 and the internal electrode layers 12, the internal electrode layers 12 are arranged on both outermost layers in the stacking direction, and the internal electrode layers 12 of the outermost layers are covered by cover layers 13. The cover layers 13 are mainly composed of a ceramic material. For example, the cover layers 13 may have the same composition as the dielectric layers 11 or may have a different composition.

A main component of the dielectric layer 11 is a ceramic material having a perovskite structure expressed by a general formula ABO₃. The perovskite structure includes ABO_{3-α} having an off-stoichiometric composition. For example, the ceramic material is such as BaTiO₃ (barium titanate), CaZrO₃ (calcium zirconate), CaTiO₃ (calcium titanate), SrTiO₃ (strontium titanate), MgTiO₃ (magnesium titanate), Ba_{1-x-y}CaₓSr_{y}Ti_{1-z}Zr_{z}O₃ (0≤x≤1, 0≤y≤1, 0≤z≤1) having a perovskite structure. Ba_{1-x-y}CaₓSr_{y}Ti_{1-z}Zr_{z}O₃ may be barium strontium titanate, barium calcium titanate, barium zirconate, barium titanate zirconate, calcium titanate zirconate, barium calcium titanate zirconate or the like.

Additives may be added to the dielectric layer 11. As additives to the dielectric layer 11, an oxide of Mg (magnesium), Mn (manganese), Mo (molybdenum), vanadium (V), chromium (Cr), or a rare earth element (Y (yttrium), Sm (samarium), Eu (europium), Gd (gadolinium), Tb (terbium), Dy (dysprosium), Ho (holmium), Er (erbium), Tm (thulium) or Yb (ytterbium), or an oxide of Co (cobalt), Ni (nickel), Li (lithium), B (boron), Na (sodium), K (potassium) or Si (silicon), or a glass including cobalt, nickel, lithium, boron, sodium, potassium or silicon.

The thickness of each of the dielectric layers 11 in the stacking direction is, for example, 0.3 μm or more and 3 μm or less. The thickness of each of the dielectric layers 11 can be measured by exposing the cross section of the multilayer ceramic capacitor 100, for example, in FIG. 18, by mechanical polishing, and then obtaining the average value of the thickness at 10 points from an image taken by a microscope such as a scanning transmission electron microscope.

A main component of the internal electrode layer 12 is Ni. The thickness of each of the internal electrode layers 12 in the stacking direction is, for example, 0.1 μm or more and 2 μm or less. The thickness of each of the internal electrode layers 12 in the T direction can be measured by exposing the cross section of the multilayer ceramic capacitor 100, for example, in FIG. 18, by mechanical polishing, and then obtaining the average value of the thickness at 10 points from an image taken by a microscope such as a scanning transmission electron microscope.

As illustrated in FIG. 18, a section, in which a set of the internal electrode layers 12 connected to the external electrode 20a face another set of the internal electrode layers 12 connected to the external electrode 20b, is a section generating electrical capacity in the multilayer ceramic capacitor 100e. Accordingly, the section is referred to as the capacity section 14. That is, the capacity section 14 is a section in which the internal electrode layers next to each other being connected to different external electrodes face each other.

A section, in which the internal electrode layers 12 connected to the external electrode 20a face each other without sandwiching the internal electrode layer 12 connected to the external electrode 20b, is referred to as the end margin 15. A section, in which the internal electrode layers 12 connected to the external electrode 20b face each other without sandwiching the internal electrode layer 12 connected to the external electrode 20a is another end margin 15. That is, the end margin 15 is a section in which a set of the internal electrode layers 12 connected to one external electrode face each other without sandwiching the internal electrode layer 12 connected to the other external electrode. The end margins 15 are sections that do not generate electrical capacity in the multilayer ceramic capacitor 100. The end margin 15 may have the same composition as the dielectric layer 11 of the capacity section 14, or may have a different composition.

As illustrated in FIG. 19, a section of the multilayer chip 10 from the two sides thereof to the internal electrode layers 12 is referred to as the side margin 16. That is, the side margin 16 is a section covering edges of the stacked internal electrode layers 12 in the extension direction toward the two side faces. The side margin 16 does not generate electrical capacity. The side margin 16 may have the same composition as the dielectric layer 11 of the capacity section 14, or may have a different composition.

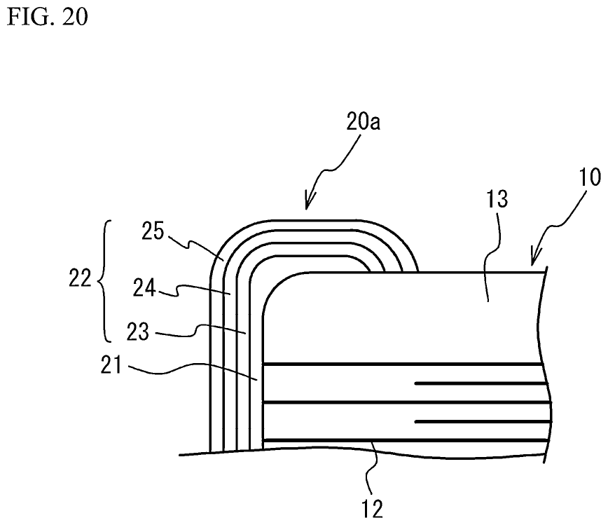

FIG. 20 is an enlarged cross-sectional view of the vicinity of the external electrode 20a. Hatching is omitted in FIG. 20. As illustrated in FIG. 20, the external electrode 20a has a structure in which the plated layer 22 is provided on the base layer 21. The base layer 21 is mainly composed of Cu. The base layer 21 may also contain a glass component. The plated layer 22 is mainly composed of a metal such as Cu, Ni, aluminum (Al), zinc (Zn), Sn, or an alloy of two or more of these. The plated layer 22 may be a plated layer of a single metal component, or may be a plurality of plating layers of different metal components. For example, the plated layer 22 has a structure in which the first plated layer 23, the second plated layer 24, and the third plated layer 25 are formed in this order from the base layer 21 side. The first plated layer 23 is, for example, a Sn plated layer. The second plated layer 24 is, for example, a Ni plated layer. The third plated layer 25 is, for example, a Sn plated layer. Although FIG. 20 illustrates the external electrode 20a, the external electrode 20b also has a similar multilayer structure.

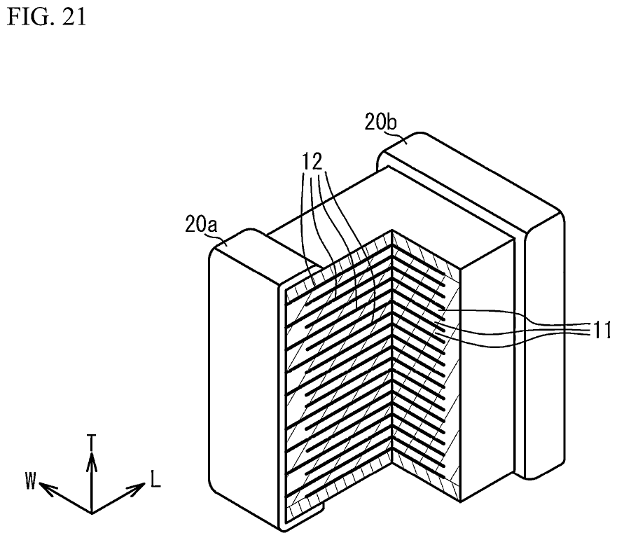

When trying to realize a large-capacity multilayer ceramic capacitor, it is important to increase the total opposing area of the internal electrode layers. In order to achieve a large capacity without increasing the mounting area, it is possible to increase the number of stacked internal electrode layers. For example, as illustrated in FIG. 21, it is possible to increase the number of stacked internal electrode layers 12 while suppressing the increase in the area of each of the internal electrode layers 12. With this configuration, it is thought that a large capacity can be realized because the total opposing area of the internal electrode layers 12 increases. However, if the number of stacked layers is large, positional deviations are likely to occur during stacking, and it becomes difficult to cut the pre-fired stack perpendicular to the stacking direction.

Therefore, the multilayer ceramic capacitor 100e according to this embodiment has a configuration in which the area of each of the internal electrode layers is large and the number of stacked layers is suppressed. Specifically, as illustrated in FIG. 17, when the height of the multilayer ceramic capacitor 100e in the T direction is height T₀, the width in the W direction is width W₀, and the length in the L direction is length L₀, the multilayer ceramic capacitor 100e has a relationship of T₀≥W₀×1.3. By adopting such a configuration, the width of the internal electrode layer 12 can be increased while the number of layers of the internal electrode layer 12 can be reduced, so that misalignment during stacking can be suppressed and the multilayer structure before firing can be cut perpendicular to the stacking direction. Note that the height T₀, width W₀, and length L₀ are the maximum dimensions in the T direction, W direction, and L direction, respectively.

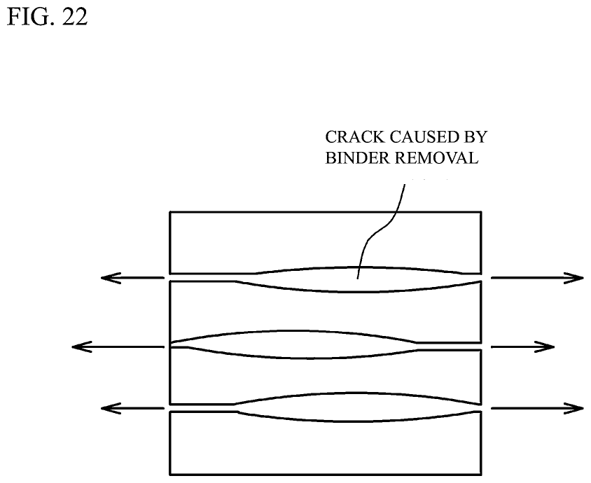

However, if the height in the T direction of the internal electrode layer 12 is large, even if a binder removal process is performed to remove the organic binder contained in the multilayer structure before firing, the binder may not be sufficiently removed because the binder discharge path is long. In this case, as illustrated in FIG. 22, the decomposition gas of the binder may remain inside the multilayer structure, which may cause cracks (de-by-cracks) or delamination.

The multilayer ceramic capacitor 100e according to this embodiment has a configuration that can achieve good binder removal characteristics even in a configuration in which the relationship T₀≥W₀×1.3 is established.

Specifically, the low melting point metal with a lower melting point than Cu, the main component of the base layer 21, is provided inside the internal electrode layer 12 or at the interface between the internal electrode layer 12 and the dielectric layer 11. The low-melting point metal is not particularly limited as long as it has a melting point lower than Cu, but is, for example, such as Ga (gallium), In (indium), Sn, Bi (bismuth), Pb (lead), or Zn. The low-melting point metal may be alloyed with Ni, the main component of the internal electrode layer 12, or may be disposed as a single metal. For example, the low melting point metal may be uniformly dispersed and disposed in the internal electrode layer 12, or may be segregated at the interface between the internal electrode layer 12 and the dielectric layer 11.

By providing the low melting point metal inside the internal electrode layer 12 or at the interface between the internal electrode layer 12 and the dielectric layer 11, the binder ejection start temperature becomes lower during the heat treatment in the binder removal process compared to when the low melting point metal is not provided. This achieves good binder removal properties and makes it possible to suppress cracks and delamination. The reason why the binder ejection start temperature becomes lower is thought to be that the low melting point metal melts at the binder ejection temperature and exerts the effect of facilitating the binder ejection.

If a sufficient amount of the low melting point metal is not added, there is a risk that a sufficiently good binder removal property is not obtained. Therefore, it is preferable to set a lower limit for the concentration of the low melting point metal added. In this embodiment, the concentration of the low melting point metal added is preferably 0.1 at % or more, more preferably 0.3 at % or more, and even more preferably 0.5 at % or more. The concentration of the low melting point metal is the amount (at %) of the low melting point metal added when the Ni of the internal electrode layer 12 is 100 at % in the entire internal electrode layer 12 sandwiched between two adjacent dielectric layers. When multiple types of low melting point metals are included, the concentration of the low melting point metal added is the total amount of the multiple types of low melting point metals.

On the other hand, if the amount of the low melting point metal added is large, it may cause the internal electrodes to become spherical due to over-sintering or abnormal grain growth of the dielectric layer. Therefore, it is preferable to set an upper limit on the concentration of the low melting point metal added. In this embodiment, the concentration of the low melting point metal added is preferably 10 at % or less, more preferably 5 at % or less, and even more preferably 2 at % or less.

The height T₀, the width W₀, and the length L₀ are not particularly limited, but for example, the height T₀ may be 0.15 μmm or more and 1.0 μmm or less, the width W₀ may be 0.1 mm or more and 0.7 μmm or less, and the length L₀ may be 0.2 μmm or more and 1.2 mm or less.

In the W direction, the stacking density of the internal electrode layers 12 is, for example, 500 layers/mm or more, 750 layers/mm or more, or 1000 layers/mm or more and 1500 layers/mm or less.

In order to achieve high capacity, T₀ is preferably 1.5 times W₀ or more, and more preferably 2.0 times W₀ or more.

If the maximum height of the internal electrode layer 12 in the T direction is a height Ta and the maximum width of the internal electrode layer 12 in the W direction is a width Wa, then, for example, Ta is 500 times or more, 700 times or more, or 1000 times or more of Wa. Also, the ratio of the height in the T direction to the width in the W direction of the capacity section 14 (T/W ratio) is, for example, 1.3 or more, 1.5 or more, or 2.0 or more.

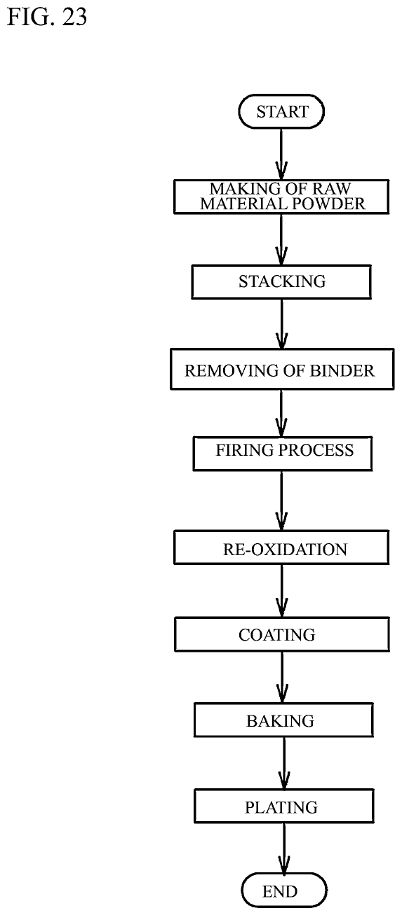

Next, a description will be given of a manufacturing method of the multilayer ceramic capacitors 100e in accordance with the sixth embodiment. FIG. 23 illustrates a manufacturing method of the multilayer ceramic capacitor 100e.

(Making process of raw material powder) A dielectric material for forming the dielectric layer 11 is prepared. The dielectric material includes the main component ceramic of the dielectric layer 11. Generally, an A site element and a B site element are included in the dielectric layer 11 in a sintered phase of grains of ABO₃. For example, barium titanate is tetragonal compound having a perovskite structure and has a high dielectric constant. Generally, barium titanate is obtained by reacting a titanium material such as titanium dioxide with a barium material such as barium carbonate and synthesizing barium titanate. Various methods can be used as a synthesizing method of the ceramic structuring the dielectric layer 11. For example, a solid-phase method, a sol-gel method, a hydrothermal method or the like can be used. The embodiments may use any of these methods.

An additive compound may be added to the resulting ceramic powder, in accordance with purposes. The additive compound may be an oxide of magnesium, manganese, molybdenum, vanadium, chromium, a rare earth element (yttrium, samarium, europium, gadolinium, terbium, dysprosium, holmium, erbium, thulium or ytterbium), or an oxide containing cobalt, nickel, lithium, boron, sodium, potassium or silicon, or glasses containing cobalt, nickel, lithium, boron, sodium, potassium or silicon.

For example, the resulting ceramic raw material powder is wet-blended with additives and is dried and crushed. Thus, a ceramic material is obtained. For example, the particle diameter may be adjusted by crushing the resulting ceramic material as needed. Alternatively, the grain diameter of the resulting ceramic powder may be adjusted by combining the crushing and classifying. With the processes, a dielectric material is obtained.

(Stacking process) Next, a binder such as polyvinyl butyral (PVB) resin, an organic solvent such as ethanol or toluene, and a plasticizer are added to the resulting dielectric material and wet-blended. With use of the resulting slurry, a dielectric green sheet ius formed on a base material by, for example, a die coater method or a doctor blade method, and then dried. The base material is, for example, PET (polyethylene terephthalate) film.

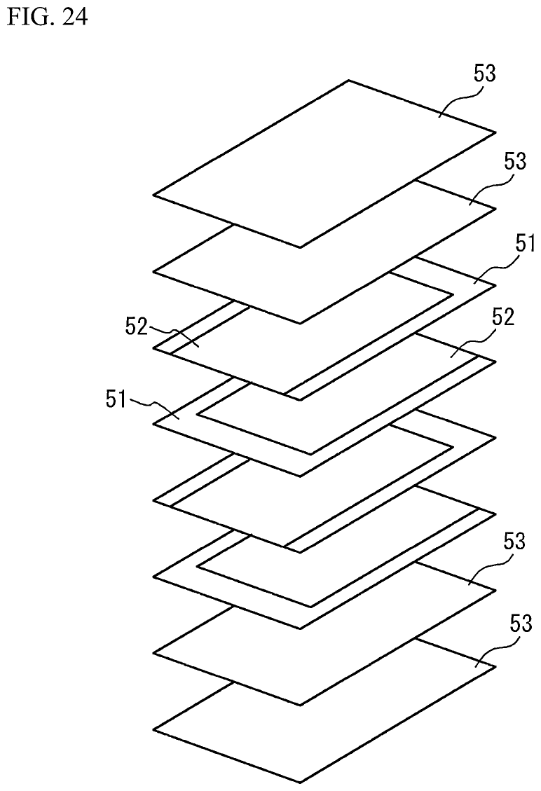

Next, as illustrated in FIG. 24, an internal electrode pattern 52 is formed on a dielectric green sheet 51. The dielectric green sheet 51 on which the internal electrode pattern 52 is formed is a stack unit. Ni powder including the low melting temperature metal of which a melting point is lower than that of Cu is used as the internal electrode pattern 52. The forming method of the internal electrode pattern may be such as printing, sputtering, or vapor deposition.

(Crimping process) Next, the dielectric green sheets 51 are peeled from the base materials. As illustrated in FIG. 24, the stack units are stacked. Next, a predetermined number of cover sheets 53 (for example, 2 to 10 layers) are stacked on the top and bottom of the multilayer structure obtained by stacking the stack units, and are thermally crimped. The cover sheet 53 can be formed by the same method as that of the dielectric green sheet.

(Removing process of binder) The binder is removed from the ceramic multilayer structure in N₂ atmosphere. The thermal treatment temperature is approximately 250 degrees C. to 700 degrees C. The thermal treatment time is 5 μminutes to 1 hour.

(Firing process) The resulting ceramic multilayer structure is fired for 10 μminutes to 2 hours in a reductive atmosphere having an oxygen partial pressure of 10⁻⁵ to 10⁻⁸ atm in a temperature range of 1100 degrees C. to 1300 degrees C. Thus, the multilayer chip 10 is obtained.

(Re-oxidizing process) A re-oxidation treatment process may be performed in N₂ gas at 600° C. to 1000° C.

(Coating process) Next, a metal paste that will become the base layer 21 is coated on the first side of the multilayer structure by a dipping method or the like. This metal paste contains glass components such as glass frit.

(Baking process) Next, the metal paste is baked at a temperature of about 700° C. to 900° C. to form the base layer 21.

(Plating process) After that, a metal coating of copper, nickel, tin, or the like may be applied to the base layer 21 by plating. For example, the first plated layer 23, the second plated layer 24, and the third plated layer 25 are formed in this order on the base layer 21. This completes the multilayer ceramic capacitor 100e.

In the manufacturing method according to this embodiment, the low melting point metal is added to the internal electrode pattern 52. By adding the low melting point metal, the binder ejection start temperature during the heat treatment in the binder removal process becomes lower than when the low melting point metal is not added. This realizes good binder removal characteristics and makes it possible to suppress cracks and delamination.

Note that in the above manufacturing method, the base layer 21 is baked after the multilayer chip 10 is fired, but this is not limited to this. For example, the base layer 21 may be fired at the same time as the multilayer chip 10 is fired.

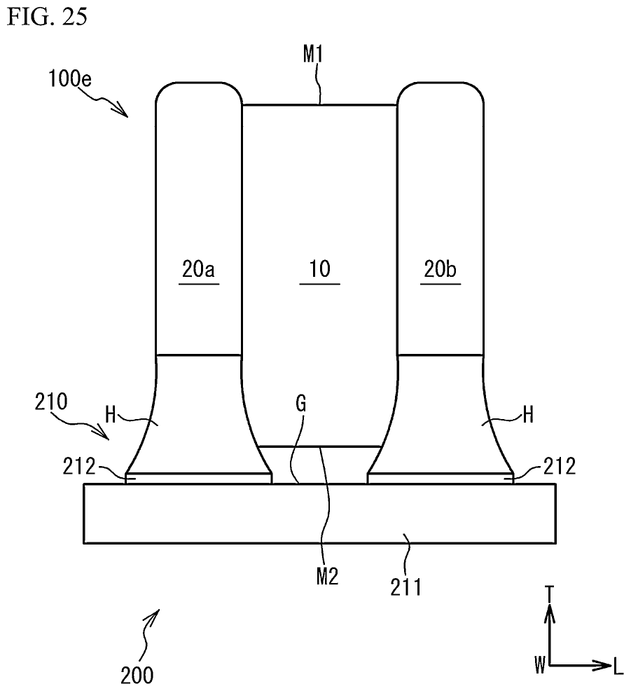

Here, the mounting of the multilayer ceramic capacitor 100e will be described. FIG. 25 is a side view of the circuit board 200 including the multilayer ceramic capacitor 100e. The circuit board 200 has the mounting board 210 on which the multilayer ceramic capacitor 100e is mounted. The mounting board 210 has the base substrate 211 that extends along the planes of the L and W directions and has the mounting surface G perpendicular to the T direction, and the pair of connection electrodes 212 provided on the mounting surface G.

On the circuit board 200, the external electrodes 20a and 20b of the multilayer ceramic capacitor 100 are connected to the pair of connection electrodes 212 of the mounting board 210 via the solder H. As a result, on the circuit board 200, the multilayer ceramic capacitor 100 is fixed to the mounting board 210 and electrically connected.

In the multilayer ceramic capacitor 100e, it is known, when the circuit board 200 is driven and a voltage is applied to the external electrodes 20a and 20b via the connection electrodes 212 of the mounting board 210, electrostriction occurs in the multilayer chip 10 due to the piezoelectric effect. The electrostriction occurring in the multilayer chip 10 causes relatively large deformation in the stacking direction of the internal electrode layers 12.

In the circuit board 200, repeated electrostriction occurs in the multilayer ceramic capacitor 100c to which an AC voltage is applied, which may cause vibration in the thickness direction of the substrate 211 of the mounting board 210. In the circuit board 200, when the vibration occurring in the substrate 211 becomes large, noise may be generated from the substrate 211, a phenomenon known as “ringing”.

However, in the multilayer ceramic capacitor 100e according to this embodiment, the stacking direction of the internal electrode layers 12 is the in-plane direction of the substrate 211, so that vibration in the thickness direction is unlikely to occur in the substrate 211 due to electrostriction of the multilayer chip 10. Also, in the multilayer ceramic capacitor 100e, the number of the internal electrode layers 12 is small, and the amount of deformation due to electrostriction is kept small, so that even if vibration occurs in the substrate 211, it is unlikely to be large enough to generate noise.

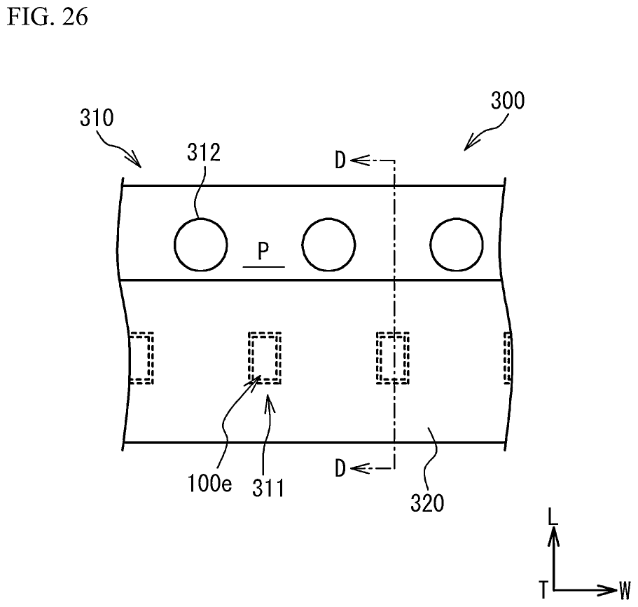

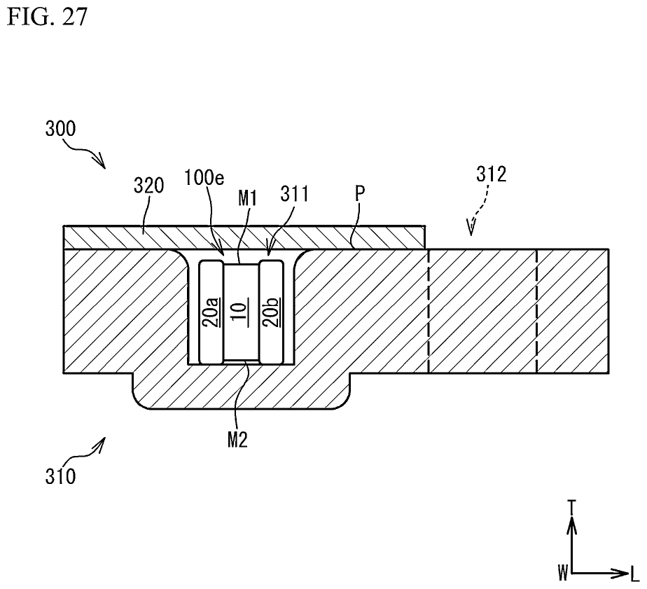

When mounting the multilayer ceramic capacitor 100e on the mounting board 210, the multilayer ceramic capacitor 100e is prepared in a packaged state as the package 300. FIG. 26 and FIG. 27 are diagrams illustrating the package 300. FIG. 26 is a partial plan view of the package 300. FIG. 27 is a cross-sectional view of the package 300 taken along a line D-D in FIG. 26.

The package 300 has the multilayer ceramic capacitor 100e, the carrier tape 310, and the top tape 320. The carrier tape 310 is configured as a long tape extending in the W direction. The carrier tape 310 has the plurality of recesses 311 arranged at intervals in the W direction, each of which accommodates each of the multilayer ceramic capacitors 100e.

The carrier tape 310 has the seal surface P, which is an upward surface perpendicular to the T direction, and the plurality of recesses 311 are recessed downward in the T direction from the seal surface P. In other words, the carrier tape 310 is configured so that the multilayer ceramic capacitors 100 in the plurality of recesses 311 can be removed from the seal surface P side.

The carrier tape 310 has the plurality of feed holes 312 that penetrate in the T direction and are arranged at intervals in the W direction at positions offset in the L direction from the row of the plurality of recesses 311. The feed holes 312 are configured as engagement holes used by the tape transport mechanism to transport the carrier tape 310 in the W direction.

In the package 300, the top tape 320 is attached to the seal surface P of the carrier tape 310 along the row of the plurality of recesses 311, and the plurality of recesses 311 containing the plurality of multilayer ceramic capacitors 100e are collectively covered by the top tape 320. As a result, the plurality of multilayer ceramic capacitors 100e are held in the plurality of recesses 311.

As illustrated in FIG. 27, in the multilayer ceramic capacitor 100e in the recess 311 of the carrier tape 310, the first main surface M1 of the multilayer chip 10 facing upward in the T direction faces the top tape 320. Also, the second main surface M2 of the multilayer chip 10 facing downward in the T direction faces the bottom surface of the recess 311.

When mounting the multilayer ceramic capacitor 100e packaged as the package 300, the top tape 320 is peeled off from the seal surface P of the carrier tape 310 along the W direction. As a result, in the package 300, the plurality of recesses 311 containing the plurality of multilayer ceramic capacitors 100e can be sequentially opened upward in the T direction.

The multilayer ceramic capacitor 100e housed in the opened recess 311 is removed with the first main surface M1 of the multilayer chip 10 facing upward in the T direction being sucked onto the tip of the suction nozzle of the mounting device. The mounting device moves the suction nozzle to move the multilayer ceramic capacitor 100e onto the mounting surface G of the mounting board 210.

Then, the mounting device releases the suction nozzle from the first main surface M1 of the multilayer chip 10 with the second main surface M2 of the multilayer chip 10 facing the mounting surface G and the external electrodes 20a and 20b aligned onto the pair of connection electrodes 212 to which the solder paste has been applied. Thus, the multilayer ceramic capacitor 100e is placed on the mounting surface G.

Then, the solder paste is melted and hardened using a reflow oven or the like for the mounting board 210 on which the multilayer ceramic capacitor 100e has been placed on the mounting surface G. As a result, the external electrodes 20a and 20b are connected to the pair of connection electrodes 212 of the mounting board 210 via the solder H, thereby obtaining the circuit board 200 illustrated in FIG. 25.

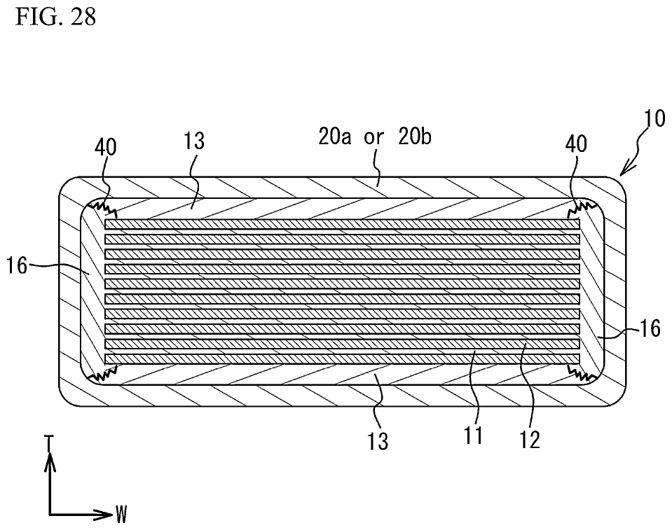

(Seventh embodiment) In the W-direction and T-direction cross sections at the positions of the external electrodes 20a and 20b, if excessive diffusion occurs from the external electrodes 20a and 20b to the internal electrode layers 12, the cracks 40 may occur in the corners near the external electrodes, as illustrated in FIG. 28. In particular, diffusion is likely to occur when the main component metal of the base layer 21 is Cu and the main component metal of the internal electrode layer 12 is Ni. Furthermore, if a low melting point metal such as that described above is disposed in the internal electrode layer 12 or at the interface between the internal electrode layer 12 and the dielectric layer 11, diffusion from the base layer 21 may be promoted when the base layer 21 is formed. Note that FIG. 28 is a view equivalent to the cross section taken along the line C-C in FIG. 17.

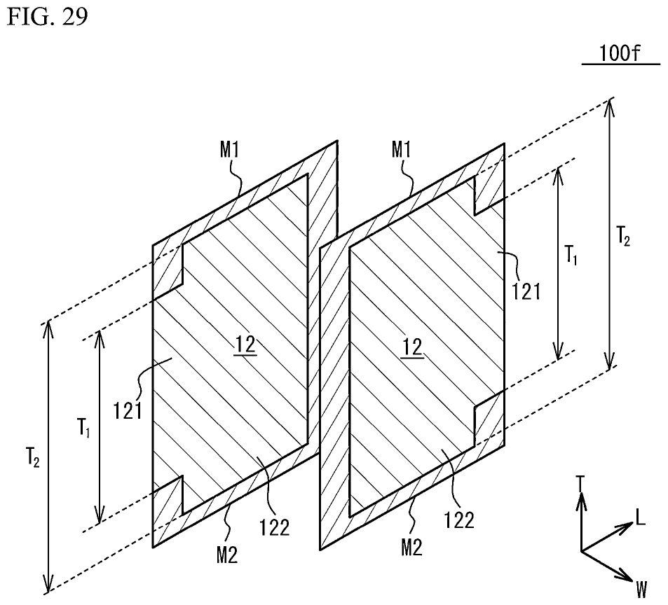

Therefore, in the multilayer ceramic capacitors 100f according to the seventh embodiment, the dimensions of each internal electrode layer 12 in the T direction are varied. As illustrated in FIG. 29, the internal electrode layer 12 connected to the external electrode 20a has the first section 121 (connection portion) connected to the external electrode 20a in a section corresponding to the end margin 15 and having the dimension T1 in the T direction, and the second section 122 having the dimension T2 in the T direction in a section corresponding to the capacity portion 14. The dimension T1 is lower than the dimension T2. In the T direction, the first section 121 is located inside the second section 122. According to this configuration, the movement distance from the external electrodes 20a and 20b to the internal electrode layer 12 is long at the corner portion, so that diffusion from the external electrodes 20a and 20b to the internal electrode layer 12 is suppressed. As a result, the occurrence of the cracks 40 is suppressed. The internal electrode layer 12 connected to the external electrode 20b also has the first section 121 having the dimension T1 and the second section 122 having the dimension T2.

For example, if T1/T2 is small, the connectivity between the external electrodes 20a, 20b and the internal electrode layer 12 may decrease, and good conduction may not be necessarily obtained. Therefore, it is preferable to set a lower limit for T1/T2. On the other hand, if T1/T2 is large, the movement distance from the external electrodes 20a and 20b to the internal electrode layer 12 may not be sufficiently long. Therefore, it is preferable to set an upper limit for T1/T2. For the above reasons, T1/T2 is preferably ½ or more, and more preferably ⅔ or more. Furthermore, T1/T2 is preferably ⅘ or less, and more preferably ¾ or less.

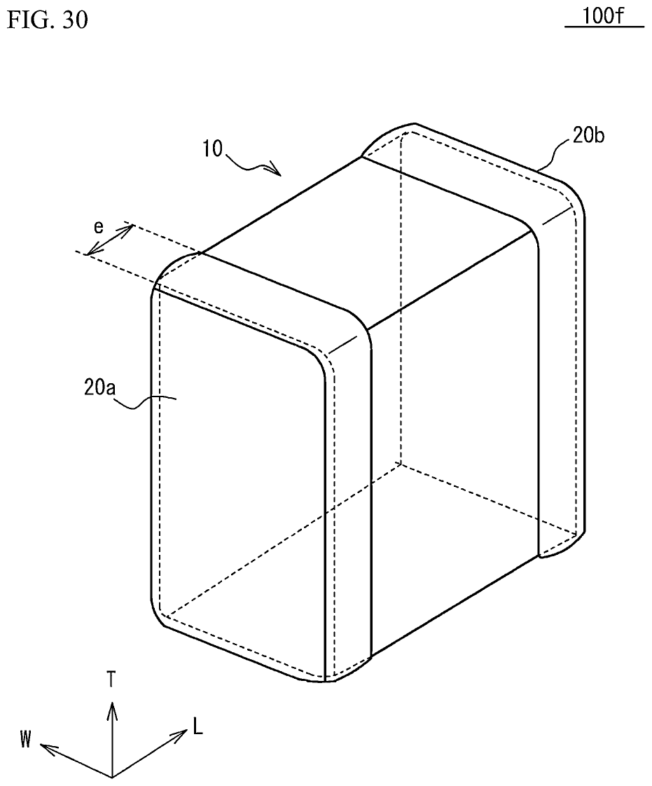

Here, as illustrated in FIG. 30, the dimension of the external electrodes 20a and 20b extending in the L direction from both end faces of the multilayer chip 10 is referred to as the dimension “e”. From the viewpoint of suppressing the cracks 40 at the corners, the dimension in the L direction of the first section 121 is preferably ⅓ or more of the dimension “e”, and more preferably ½ or more of the dimension “e”.

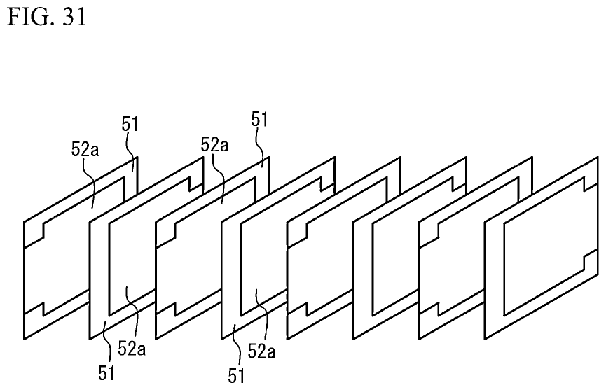

The multilayer ceramic capacitors 100f according to this embodiment can be obtained by stacking the dielectric green sheets 51 on which the internal electrode patterns 52a having the dimensions T1 and T2 are formed, as illustrated in FIG. 31, for example.

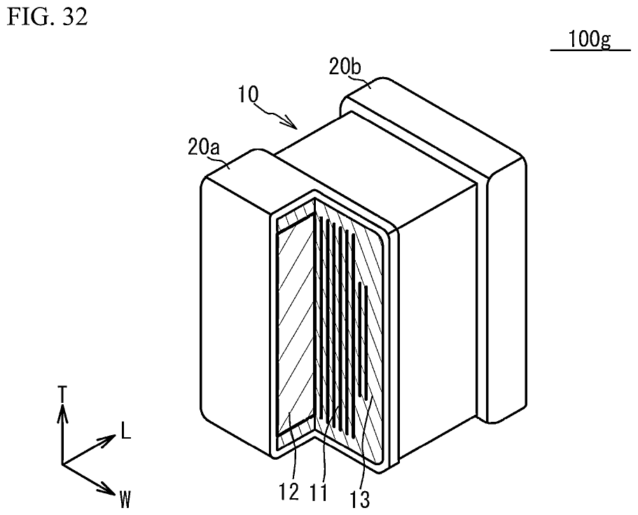

(Eighth embodiment) In the seventh embodiment, all the internal electrode layers 12 have the first section 121 and the second section 122, but some of the internal electrode layers 12 may have the first section 121 and the second section 122. For example, as illustrated in FIG. 32, it is preferable that one or more internal electrode layers 12 have the first section 121 and the second section 122 from the outermost internal electrode layer 12 toward the inside. The internal electrode layer 12 having the first section 121 and the second section 122 is referred to as the internal electrode layer 12 of the outer section. The internal electrode layers 12 that are located inside the internal electrode layers 12 in the outer section and have a substantially constant height in the T direction are referred to as the internal electrode layers 12 in the inner section.

From the viewpoint of suppressing diffusion from the external electrodes 20a and 20b to the internal electrode layers 12, it is preferable that the internal electrode layers 12 in the outer section account for 10% or more of the total number of layers, and it is more preferable that the internal electrode layers 12 in the outer section account for 25% or more of the total number of layers. On the other hand, from the viewpoint of reducing poor connections between the external electrodes 20a, 20b and the internal electrode layers 12, it is preferable that the internal electrode layers 12 in the outer section account for 50% or less of the total number of layers, and it is more preferable that the internal electrode layers 12 in the outer section account for 40% or less of the total number of layers.

The number of layers of the internal electrode layers 12 in the outer section on one side in the W direction of the internal electrode layers 12 in the inner section is preferably the same as the number of layers of the internal electrode layers 12 in the outer section on the other side in the W direction.

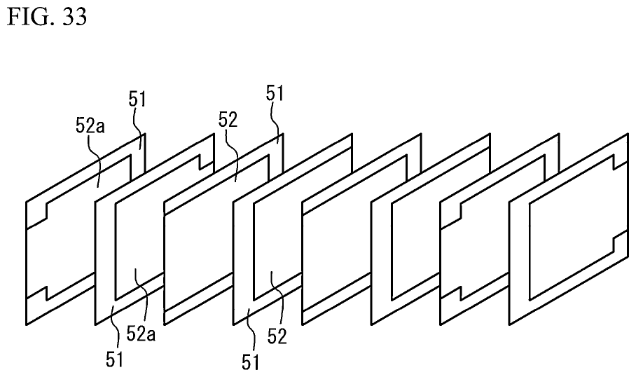

A multilayer ceramic capacitor 100g according to this embodiment can be obtained, for example, by stacking the dielectric green sheets 51 on which the internal electrode pattern 52a having the dimensions T1 and T2 is formed, and the dielectric green sheets 51 on which the internal electrode pattern 52 having a constant dimension in the T direction is formed, as illustrated in FIG. 33.

Note that, although the above embodiments have been described with respect to a multilayer ceramic capacitor as an example of a ceramic electronic component, this is not limiting. For example, the configuration of each of the above embodiments can also be applied to other multilayer ceramic electronic components, such as varistors and thermistors.

### EXAMPLES

Below, multilayer ceramic capacitors according to each embodiment were fabricated and their characteristics were examined.

(Example 1) In Example 1, the multilayer ceramic capacitors described in the first embodiment were fabricated. First, a slurry mainly composed of BaTiO₃ was mixed and applied to obtain a dielectric green sheet. An internal electrode pattern was printed on each dielectric green sheet. Nickel powder was used for the internal electrode pattern, and Sn powder was added. The concentration of Sn added to Ni was 1.0 at %. 250 layers of the obtained stack unit were stacked to obtain a multilayer structure.

A slurry mainly composed of BaTiO₃ was mixed and applied to obtain a cover sheet. A number of cover sheets were stacked and pressed on the top and bottom of the multilayer structure in the stacking direction, and then a binder removal process was performed. Then, the multilayer structure was fired and re-oxidized. A metal paste of which a main component was Cu was applied to two end faces of the obtained multilayer chip, and baked at around 800° C. Through these processes, a multilayer ceramic capacitor was produced in which 250 internal electrode layers were stacked (length L₀: 0.6 μmm, width W₀: 0.3 μmm, height T₀: 0.3 μmm).

In the fired multilayer ceramic capacitor, the thickness of each internal electrode layer in the T direction was 0.5 μm, and the thickness of each dielectric layer in the T direction was 0.5 m. The thickness of each cover layer in the T direction was 25 μm. The thickness of each side margin in the W direction was 25 μm. In each internal electrode layer, the dimension W2 in the W direction was made larger in the capacity section, and the dimension W1 in the W direction was made smaller than W2 in the end margin. The dimension W2 of the internal electrode layer in the capacity section was 250 μm, and the dimension W1 of the internal electrode layer in the end margin was 150 μm. The length of each end margin in the L direction was 15 μm. The dimension “e” of each external electrode extending in the L direction from both end faces of the multilayer chip was 20 μm.

(Example 2-1) In Example 2-1, the multilayer ceramic capacitors as described in the second embodiment were fabricated. The number of stacked internal electrode layers was 350. The length L₀ was 0.6 μmm, the width W₀ was 0.3 μmm, and the height T₀ was 0.4 μmm. The other conditions were the same as in Example 1.

(Example 2-2) In Example 2-2, the multilayer ceramic capacitors as described in the second embodiment were fabricated. The number of stacked internal electrode layers was 450. The length L₀ was 0.6 μmm, the width W₀ was 0.3 μmm, and the height T₀ was 0.5 μmm. The other conditions were the same as in Example 1.

(Example 3) In Example 3, the multilayer ceramic capacitors described in the third embodiment were fabricated. The number of stacked internal electrode layers was 450. The length L₀ was 0.6 μmm, the width W₀ was 0.3 μmm, and the height T₀ was 0.5 μmm. In each of the 50 internal electrode layers in the outer section, the dimension W2 in the W direction was made larger in the capacity section, and the dimension W1 in the W direction was made smaller than W2 in the end margin. The dimension W2 of the internal electrode layer in the capacity section was 250 μm, and the dimension W1 of the internal electrode layer in the end margin was 150 μm. In each of the 350 internal electrode layers in the inner section, the dimension in the W direction of the internal electrode layer in the capacity section and the dimension in the W direction of the internal electrode layer in the end margin were 250 μm. The other conditions were the same as in Example 1.

(Example 4-1) In Example 4-1, the multilayer ceramic capacitors described in the fourth embodiment were fabricated. The number of layers of the internal electrode layer was 250. In the fired multilayer ceramic capacitor, the length L₀ was 0.6 mm, the width W₀ was 0.3 mm, and the height T₀ was 0.5 mm. The thickness of each internal electrode layer in the W direction was 0.5 μm, and the thickness of each dielectric layer in the W direction was 0.5 km. The thickness of each cover layer in the W direction was 25 μm. The thickness of each side margin in the T direction was 25 km. In each internal electrode layer, the dimension T2 in the T direction was made larger in the capacity section, and the dimension T1 in the T direction was made smaller than T2 in the end margin. The dimension T2 of the internal electrode layer in the capacity section was 450 μm, and the dimension T1 of the internal electrode layer in the end margin was 300 μm. The length of each end margin in the L direction was 15 μm. The dimension “e” of each external electrode extending in the L direction from both end faces of the multilayer chip was 20 μm.

(Example 4-2) In Example 4-2, the multilayer ceramic capacitors described in the fourth embodiment were fabricated. The number of layers of the internal electrode layers was 250. In the fired multilayer ceramic capacitor, the length L₀ was 0.6 mm, the width W₀ was 0.3 mm, and the height T₀ was 0.4 mm. The thickness of each internal electrode layer in the W direction was 0.5 μm, and the thickness of each dielectric layer in the W direction was 0.5 km. The thickness of each cover layer in the W direction was 25 μm. The thickness of each side margin in the T direction was 25 μm. In each internal electrode layer, the dimension T2 in the T direction was made larger in the capacity section, and the dimension T1 in the T direction was made smaller than T2 in the end margin. The dimension T2 of the internal electrode layer in the capacity section was 350 μm, and the dimension T1 of the internal electrode layer in the end margin was 250 μm. The length of each end margin in the L direction was 15 μm. The dimension e of each external electrode extending in the L direction from both end faces of the multilayer chip was 20 μm.

(Example 5) In Example 5, the multilayer ceramic capacitors described in the fifth embodiment were fabricated. In each of the 50 internal electrode layers in the outer section, the dimension T2 in the T direction was made larger in the capacity section, and the dimension T1 in the T direction was made smaller than T2 in the end margin. The dimension T2 of the internal electrode layer in the capacity section was 450 μm, and the dimension T1 of the internal electrode layer in the end margin was 300 μm. In each of the 150 internal electrode layers in the inner section, the dimension in the T direction of the internal electrode layer in the capacity section and the dimension in the T direction of the internal electrode layer in the end margin were 450 μm. The other conditions were the same as in Example 4.

Table 1 shows the conditions of Examples 1 to 5 and Comparative Examples 1 and 2.

TABLE 1

| | | | | | | W1 | W2 | END | |
|---|---|---|---|---|---|---|---|---|---|
| | ADDED | L₀ | W₀ | T₀ | STACK | or T1 | or T2 | MARGIN | e |
| | METAL | (mm) | (mm) | (mm) | NUMBER | (μm) | (μm) | (μm) | (μm) |
| EXAMPLE 1 | Sn | 0.6 | 0.3 | 0.3 | 250 | 150 | 250 | 15 | 20 |
| EXAMPLE 2-1 | Sn | 0.6 | 0.3 | 0.4 | 250 | 150 | 250 | 15 | 20 |
| EXAMPLE 2-2 | Sn | 0.6 | 0.3 | 0.5 | 450 | 150 | 250 | 15 | 20 |
| EXAMPLE 3 | Sn | 0.6 | 0.3 | 0.5 | OUTER: | OUTER: 150 | 250 | 15 | 20 |
| | | | | | 50 AND 50 | INNER: 250 | | | |
| | | | | | INNER:350 | | | | |
| EXAMPLE 4-1 | Sn | 0.6 | 0.3 | 0.5 | 250 | 300 | 450 | 15 | 20 |
| EXAMPLE 4-2 | Sn | 0.6 | 0.3 | 0.4 | 250 | 250 | 350 | 15 | 20 |
| EXAMPLE 5 | Sn | 0.6 | 0.3 | 0.5 | OUTER: | OUTER: 300 | 450 | 15 | 20 |
| | | | | | 50 AND 50 | INNER: 450 | | | |
| | | | | | INNER:150 | | | | |
| COMPARATIVE | Sn | 0.6 | 0.3 | 0.3 | 250 | 250 | 250 | 15 | 20 |
| EXMPLE 1 | | | | | | | | | |
| COMPARATIVE | Sn | 0.6 | 0.3 | 0.5 | 450 | 250 | 250 | 15 | 20 |
| EXMPLE 2 | | | | | | | | | |

100 samples were prepared for each of Comparative Examples 1 and 2 and Examples 1 to 5. No cracks were observed in Examples 1 to 5. The reason why no cracks were observed is believed to be that in at least one of the multiple internal electrode layers from the outermost layer, the width of the connection portion connected to the external electrode is narrower than the width of other areas, so that the movement distance from the base layer to the internal electrode layer was longer at the corners, and diffusion from the base layer to the internal electrode layer was suppressed. In contrast, cracks were observed in Comparative Examples 1 and 2. The reason why cracks were observed is believed to be that the movement distance from the base layer to the internal electrode layer was shorter at the corners, and diffusion from the base layer to the internal electrode layer was promoted.

TABLE 2

| | CRACK |
|---|---|
| EXAMPLE 1 | NONE |
| EXAMPLE 2-1 | NONE |
| EXAMPLE 2-2 | NONE |
| EXAMPLE 3 | NONE |
| EXAMPLE 4-1 | NONE |
| EXAMPLE 4-2 | NONE |
| EXAMPLE 5 | NONE |
| COMPARATIVE EXMPLE 1 | PRESENCE |
| COMPARATIVE EXMPLE 2 | PRESENCE |

(Example 6) In Example 6, the multilayer ceramic capacitors described in the sixth embodiment were fabricated. First, a slurry of which a main component was BaTiO₃ was mixed and coated to obtain a dielectric green sheet. An internal electrode pattern was printed on each dielectric green sheet. Nickel powder was used for the internal electrode pattern, and Sn powder was added. The concentration of Sn added to Ni was 1.0 at %. In the T direction, the height of each internal electrode pattern was lower than the height of the dielectric green sheet. 250 layers of the obtained stack units were stack to obtain a multilayer structure.

A slurry of which a main component was BaTiO₃ was mixed and applied to obtain a cover sheet. A number of cover sheets were stacked and pressed on the top and bottom of the multilayer structure in the stacking direction, and then barrel polishing was performed and a binder removal process was performed. Then, the multilayer structure was fired and re-oxidized. A metal paste of which a main component was Cu was applied to two end faces of the obtained multilayer chip and baked at around 800° C. Through these processes, multilayer ceramic capacitors with 250 internal electrode layers stacked was produced, with a length L₀ of 0.6 mm, a width W₀ of 0.3 mm, and a height T₀ of 0.5 mm.

In the fired multilayer ceramic capacitors, the thickness of each internal electrode layer in the W direction was 0.5 μm, and the thickness of each dielectric layer in the W direction was 0.5 μm. The thickness of each cover layer in the W direction was 25 μm. The thickness of each side margin in the T direction was 25 μm. The dimension of each internal electrode layer in the T direction (T1=T2) was 450 μm. The length of each end margin in the L direction was 40 μm.

(Example 7) In Example 7, the multilayer ceramic capacitors described in the seventh embodiment were fabricated. In each internal electrode layer, the dimension T2 in the T direction was made larger in the capacity section, and the dimension T1 in the T direction was made smaller than T2 in the end margin. The dimension T2 of the internal electrode layer in the capacity section was 450 μm, and the dimension T1 of the internal electrode layer in the end margin was 300 μm. The other conditions were the same as in Example 6.

(Example 8) In Example 8, the multilayer ceramic capacitors described in the eighth embodiment were fabricated. In each of the 50 internal electrode layers in the outer section, the dimension T2 in the T direction was made larger in the capacity section, and the dimension T1 in the T direction was made smaller than T2 in the end margin. The dimension T2 of the internal electrode layer in the capacity section was 450 μm, and the dimension T1 of the internal electrode layer in the end margin was 300 μm. In each of the 150 internal electrode layers in the inner section, the dimension T2 of the internal electrode layer in the capacity section and the dimension T1 in the end margin were 450 μm. The other conditions were the same as in Example 6.

(Example 9) In Example 9, the printing width of the internal electrode pattern was changed from that in Example 6 so that the dimension in the T direction of each internal electrode layer was 350 μm, and the multilayer ceramic capacitors were fabricated in which 250 internal electrode layers were stacked, with a length L₀ of 0.6 mm, a width W₀ of 0.3 mm, and a height T₀ of 0.4 mm. The other conditions were the same as in Example 6.

(Comparative Example 3) In Comparative Example 3, Sn was not added to the internal electrode pattern. The other conditions were the same as in Example 6.

Table 3 shows the conditions for Examples 6 to 9 and Comparative Example 3.

TABLE 3

| | | ADDED | | | | | | END |
|---|---|---|---|---|---|---|---|---|
| | ADDED | AMOUNT | L₀ | W₀ | T₀ | T1 | T2 | MARGIN |
| | METAL | (at %) | (mm) | (mm) | (mm) | (μm) | (μm) | (μm) |
| EXAMPLE 6 | Sn | 1.0 | 0.6 | 0.3 | 0.5 | 450 | 450 | 40 |
| EXAMPLE 7 | Sn | 1.0 | 0.6 | 0.3 | 0.5 | 300 | 450 | 40 |
| EXAMPLE 8 | Sn | 1.0 | 0.6 | 0.3 | 0.5 | OUTER: 300 | 450 | 40 |
| | | | | | | INNER: 450 | | |
| EXAMPLE 9 | Sn | 1.0 | 0.6 | 0.3 | 0.4 | 350 | 350 | 40 |
| COMPARATIVE | — | | 0.6 | 0.3 | 0.5 | 450 | 450 | 40 |
| EXAMPLE 3 | | | | | | | | |

100 samples were fabricated for each of Comparative Example 3 and Examples 6 to 9. As illustrated in Table 4, no cracks were observed in Examples 6 to 9. The reason why no cracks were observed is thought to be that the binder discharge start temperature was lowered in the binder removal process due to the presence of a low melting point metal inside the internal electrode layer or at the interface between the internal electrode layer and the dielectric layer, and the binder was sufficiently removed. On the other hand, cracks were observed in Comparative Example 3. This is thought to be because the binder was not sufficiently removed due to the lack of addition of a low melting point metal.

TABLE 4

| | CRACK |
|---|---|
| EXAMPLE 6 | NONE |
| EXAMPLE 7 | NONE |
| EXAMPLE 8 | NONE |
| EXAMPLE 9 | NONE |
| COMPARATIVE EXAMPLE 3 | PRESENCE |

Although the embodiments of the present invention have been described in detail, it is to be understood that the various change, substitutions, and alterations could be made hereto without departing from the spirit and scope of the invention.

1. A ceramic electronic device comprising:
a multilayer chip that has a substantially rectangular parallelepiped shape in which a plurality of dielectric layers and a plurality of internal electrode layers of which a main component is Ni are alternately stacked, and is formed so that the plurality of internal electrode layers are alternately exposed to opposing first and second end faces of the rectangular parallelepiped shape; and
a pair of external electrodes that are formed respectively on the first end face and the second end face and have contact layers respectively contacting the first end face and the second end face and containing Cu as a main component,
wherein the plurality of internal electrode layers and the contact layers contain a low melting point metal having a melting point lower than that of Cu, and
wherein one or more of the plurality of internal electrode layers from an outermost one have a connection portion connected to one of the pair of external electrodes, a width of the connection portion being narrower than other region of the one or more of the plurality of internal electrode layers.

2. The ceramic electronic device as claimed in claim 1,
wherein the low melting point metal is at least one of Ga, In, Sn, Bi, Zn or Al.

3. The ceramic electronic device as claimed in claim 1,
wherein a number of the one or more of the plurality of internal electrode layers is, in total, 10% or more of a total number of the plurality of internal electrode layers.

4. The ceramic electronic device as claimed in claim 1,
wherein a width of the connection portion is ½ or more and ⅘ or less of a width of internal electrode layers in a section where internal electrode layers connected to different external electrodes face each other.

5. The ceramic electronic device as claimed in claim 1,
wherein a length of the connection portion in a direction in which the first end face and the second end face are opposite to each other is equal to or greater than ⅓ of a distance that the pair of external electrodes extend from the first end face or the second end face to at least any one of four faces of the multilayer chip other than the first end face and the second end face.

6. The ceramic electronic device as claimed in claim 1,
wherein, when directions orthogonal to a direction in which the first end face and the second end face are opposite to each other and orthogonal to each other are defined as a first direction and a second direction and a direction in which the plurality of internal electrode layers are stacked is defined as the first direction, the dimension of the ceramic electronic device in the first direction is 1.3 times or more larger than the dimension of the ceramic electronic device in the second direction.

7. The ceramic electronic device as claimed in claim 1, wherein, when directions orthogonal to a direction in which the first end face and the second end face are opposite to each other and orthogonal to each other are defined as a first direction and a second direction and a direction in which the plurality of internal electrode layers are stacked is defined as the second direction, the dimension of the ceramic electronic device in the first direction is 1.3 times or more the dimension of the ceramic electronic device in the second direction.

8. The ceramic electronic device as claimed in claim 1,
wherein a thickness of each of the plurality of internal electrode layers is 0.1 μm or more and 2 μm or less.

9. The ceramic electronic device as claimed in claim 1,
wherein a thickness of each of the plurality of dielectric layers is 0.3 μm or more and 10 m or less.

10. A package comprising:
a ceramic electronic device as claimed in claim 1;
a carrier tape that has a sealing surface orthogonal to a first direction, and a recess recessed in the first direction from the sealing surface for housing the ceramic electronic component; and
a top tape that is attached to the sealing surface and cover the recess,
wherein the first direction and a second direction are orthogonal to a direction in which the first end face and the second end face are opposite to each other and are orthogonal to each other.

11. A circuit board comprising:
a ceramic electronic device as claimed in claim 1; and
a mounting board that has a mounting surface orthogonal to a first direction, and a pair of connection electrodes each of which is connected to each of the pair of external electrodes of the ceramic electronic device via a solder,
wherein the first direction and a second direction are orthogonal to a direction in which the first end face and the second end face are opposite to each other and are orthogonal to each other.

12. A manufacturing method of a ceramic electronic device comprising:
firing a multilayer structure in which a plurality of stack units are stacked, each of the stack units having a structure in which an internal electrode pattern which is made of Ni as a main component and to which a low melting point metal having a lower melting point than Cu is added is formed on a dielectric green sheet; and
forming a layer including the low melting metal as a main component on a first end face and a second end face of the multilayer structure before firing the multilayer structure of after firing the multilayer structure,
wherein, in internal electrode patterns of one or more layers from an outermost layer among the plurality of internal electrode patterns, a width of a connection portion connected to the layer including the low melting point metal is narrower than a width of other region of the connection portion.

13. A ceramic electronic device of which a size in a first direction is 1.3 times or more of a size in a second direction orthogonal to the first direction, the device comprising:
a multilayer chip that has a substantially rectangular parallelepiped shape in which a plurality of dielectric layers and a plurality of internal electrode layers of which a main component is Ni are alternately stacked, and is formed so that the plurality of internal electrode layers are alternately exposed to opposing first and second end faces in a third direction orthogonal to the first direction and the second direction of the rectangular parallelepiped shape; and
a pair of external electrodes that are formed respectively on the first end face and the second end face and have contact portions respectively contacting the first end face and the second end face and containing Cu as a main component,
wherein a low melting-point metal having a melting point lower than that of Cu is provided at least one of inside the plurality of internal electrode layers or at interfaces between the plurality of internal electrode layers and the plurality of dielectric layers.

14. The ceramic electronic device as claimed in claim 13,
wherein the low melting point metal is at least one of Ga, In, Sn, Bi, Pb or Zn.

15. The ceramic electronic device as claimed in claim 13,
wherein one or more of the plurality of internal electrode layers from an outermost one have a connection portion connected to one of the pair of external electrodes, a width of the connection portion being narrower than other region of the one or more of the plurality of internal electrode layers.

16. The ceramic electronic device as claimed in claim 15,
wherein a number of the one or more of the plurality of internal electrode layers is, in total, 10% or more and 50% or less of a total number of the plurality of internal electrode layers.

17. The ceramic electronic device as claimed in claim 15,
wherein a width of the connection portion in the first direction is ½ or more and ⅘ or less of a width of internal electrode layers in the first direction in a section where internal electrode layers connected to different external electrodes face each other.

18. The ceramic electronic device as claimed in claim 13,
wherein a thickness of each of the plurality of internal electrode layers is 0.1 μm or more and 2 μm or less.

19. The ceramic electronic device as claimed in claim 1,
wherein a thickness of each of the plurality of dielectric layers is 0.3 μm or more and 3 m or less.

20. A package comprising:
a ceramic electronic device as claimed in claim 13;
a carrier tape that has a sealing surface orthogonal to the first direction, and a recess recessed in the first direction from the sealing surface for housing the ceramic electronic component; and
a top tape that is attached to the sealing surface and cover the recess.

21. A circuit board comprising:
a ceramic electronic device as claimed in claim 13; and
a mounting board that has a mounting surface orthogonal to the first direction, and a pair of connection electrodes each of which is connected to each of the pair of external electrodes of the ceramic electronic device via a solder.

22. A manufacturing method of a ceramic electronic device of which a size in a first direction is 1.3 times or more of a size in a second direction orthogonal to the first direction, the method comprising:
firing a multilayer structure in which a plurality of stack units are stacked in the second direction, each of the stack units having a structure in which an internal electrode pattern which is made of Ni as a main component and to which a low melting point metal having a lower melting point than Cu is added is formed on a dielectric green sheet; and
forming a layer including Cu on a first end face and a second end face of the multilayer structure opposing in a third direction orthogonal to the first direction and the second direction before firing the multilayer structure of after firing the multilayer structure.
